(19) United States
(12) Patent Application Publication
(10) Pub. No.: US 2025/0280547 A1
(43) Pub. Date: Sep. 4, 2025

(54) MEMORY DEVICE

(71) Applicant: Kioxia Corporation, Tokyo (JP)

(72) Inventors: Hiroshi MAEJIMA, Tokyo (JP); Katsuaki ISOBE, Yokohama Kanagawa (JP); Tetsuaki UTSUMI, Yokohama Kanagawa (JP); Nobuaki OKADA, Kawasaki Kanagawa (JP); Masaki UNNO, Fujisawa Kanagawa (JP); Keisuke NAKATSUKA, Kuwana Mie (JP); Hiroshi SHINOHARA, Yokosuka Kanagawa (JP)

(73) Assignee: Kioxia Corporation, Tokyo (JP)

(21) Appl. No.: 18/829,338

(22) Filed: Sep. 10, 2024

(30) Foreign Application Priority Data
Mar. 4, 2024 (JP) 2024-032311

(51) Int. Cl. H10B 80/00; G11C 16/08; G11C 16/26; H01L 23/00; H01L 25/065; H01L 25/18; H10B 43/40

(52) U.S. Cl. CPC H10B 80/00; G11C 16/08; G11C 16/26; H01L 24/08; H01L 25/0657; H01L 25/18; H10B 43/40; H01L 2224/08145; H01L 2225/06541; H01L 2924/1431; H01L 2924/14511

(57) ABSTRACT

A memory device includes: a first chip including a memory cell array having a word line and a bit line; a second chip including a first substrate and a first circuit provided on the first substrate, the second chip being in contact with the first chip; a third chip including a second substrate and a second circuit provided on the second substrate, the third chip being in contact with the first chip or the second chip; and an input/output pad. The first chip and the second chip are arranged in this order in a first direction from the word line to the bit line. The first circuit includes a first transistor connected to the bit line and a second transistor connected to the word line. The second circuit includes a third transistor connected to the input/output pad.

### CROSS-REFERENCE TO RELATED APPLICATIONS

This application is based upon and claims the benefit of priority from Japanese Patent Application No. 2024-032311, filed Mar. 4, 2024, the entire contents of which are incorporated herein by reference.

### FIELD

Embodiments described herein relate generally to a memory device.

### BACKGROUND

A NAND flash memory has been known as a memory device capable of storing data in a nonvolatile manner. In a memory device such as a NAND flash memory, a three-dimensional memory structure is adopted for high integration and large capacity. The three-dimensional memory structure and a CMOS circuit for controlling the memory structure may be provided on separate chips. In this case, the memory device is formed by bonding a memory chip provided with the three-dimensional memory structure and a circuit chip provided with the CMOS circuit.

### BRIEF DESCRIPTION OF DRAWINGS

FIG. 1 is a block diagram illustrating a configuration of a memory system including a memory device according to a first embodiment.

FIG. 2 is a circuit diagram illustrating an example of a configuration of a memory cell array according to the first embodiment.

FIG. 3 is a circuit diagram illustrating an example of connection among the memory cell array, a row decoder module, and a driver module according to the first embodiment.

FIG. 4 is a block diagram illustrating an example of connection between the memory cell array and a sense amplifier module according to the first embodiment.

FIG. 5 is a circuit diagram illustrating an example of a configuration of the sense amplifier module according to the first embodiment.

FIG. 6 is a plan view illustrating an example of a planar layout of the memory cell array according to the first embodiment.

FIG. 7 is a plan view illustrating an example of a planar layout in a memory region of the memory cell array according to the first embodiment.

FIG. 8 is a cross-sectional view taken along a line VIII-VIII of FIG. 7, illustrating an example of a cross-sectional structure in the memory region of the memory cell array according to the first embodiment.

FIG. 9 is a cross-sectional view taken along a line IX-IX of FIG. 8, illustrating an example of a cross-sectional structure of a memory pillar according to the first embodiment.

FIG. 10 is a plan view illustrating an example of a planar layout in a hookup region of the memory cell array according to the first embodiment.

FIG. 11 is a cross-sectional view taken along a line XI-XI of FIG. 10, illustrating an example of a cross-sectional structure in a hookup region of the memory cell array according to the first embodiment.

FIG. 12 is a perspective view illustrating an example of a bonded structure of the memory device and a planar layout of each chip according to the first embodiment.

FIG. 13 is a cross-sectional view taken along a plane XIII of FIG. 12, illustrating an example of a cross-sectional structure of the memory device according to the first embodiment.

FIG. 14 is a cross-sectional view taken along a plane XIV of FIG. 12, illustrating an example of a cross-sectional structure of the memory device according to the first embodiment.

FIG. 15 is a perspective view illustrating an example of a bonded structure of a memory device and a planar layout of each chip according to a modification of the first embodiment.

FIG. 16 is a cross-sectional view taken along a plane XVI of FIG. 15, illustrating an example of a cross-sectional structure of a memory device according to the modification of the first embodiment.

FIG. 17 is a cross-sectional view illustrating an example of a cross-sectional structure of a memory device according to a second embodiment.

FIG. 18 is a cross-sectional view illustrating an example of the cross-sectional structure of the memory device according to the second embodiment.

FIG. 19 is a cross-sectional view illustrating an example of a cross-sectional structure of a memory device according to a modification of the second embodiment.

FIG. 20 is a perspective view illustrating an example of a bonded structure of a memory device and a planar layout of each chip according to a third embodiment.

FIG. 21 is a cross-sectional view taken along a plane XXI of FIG. 20, illustrating an example of a cross-sectional structure of the memory device according to the third embodiment.

FIG. 22 is a cross-sectional view taken along a plane XXII of FIG. 20, illustrating an example of a cross-sectional structure of the memory device according to the third embodiment.

FIG. 23 is a perspective view illustrating an example of a bonded structure of a memory device and a planar layout of each chip according to a modification of the third embodiment.

FIG. 24 is a cross-sectional view taken along a plane XIV of FIG. 23, illustrating an example of a cross-sectional structure of the memory device according to the modification of the third embodiment.

FIG. 25 is a perspective view illustrating an example of a bonded structure of a memory device and a planar layout of each chip according to a fourth embodiment.

FIG. 26 is a cross-sectional view taken along a plane XXVI of FIG. 25, illustrating an example of a cross-sectional structure of the memory device according to the fourth embodiment.

FIG. 27 is a cross-sectional view taken along a plane XXVII of FIG. 25, illustrating an example of a cross-sectional structure of the memory device according to the fourth embodiment.

FIG. 28 is a schematic diagram illustrating an example of a wiring structure of the memory device according to the fourth embodiment.

FIG. 29 is a cross-sectional view illustrating an example of a cross-sectional structure of a memory device according to a fifth embodiment.

FIG. 30 is a cross-sectional view illustrating an example of a cross-sectional structure of the memory device according to the fifth embodiment.

### DETAILED DESCRIPTION

In general, according to one embodiment, a memory device includes: a first chip including a memory cell array having a word line and a bit line; a second chip including a first substrate and a first circuit provided on the first substrate, the second chip being in contact with the first chip; a third chip including a second substrate and a second circuit provided on the second substrate, the third chip being in contact with the first chip or the second chip; and an input/output pad. The first chip and the second chip are arranged in this order in a first direction from the word line to the bit line. The first circuit includes a first transistor connected to the bit line and a second transistor connected to the word line. The second circuit includes a third transistor connected to the input/output pad.

Hereinafter, embodiments will be described with reference to the drawings. Dimensions and ratios of the drawings are not necessarily the same as actual ones.

Note that, in the following description, components having substantially the same functions and configurations are denoted by the same reference numerals. In a case where elements having similar configurations are particularly distinguished from each other, different characters or numbers may be added to the end of the same reference numeral.

### 1. First Embodiment

A first embodiment will be described.

### 1.1 Functional Configuration

A functional configuration according to the first embodiment will be described.

### 1.1.1 Memory System

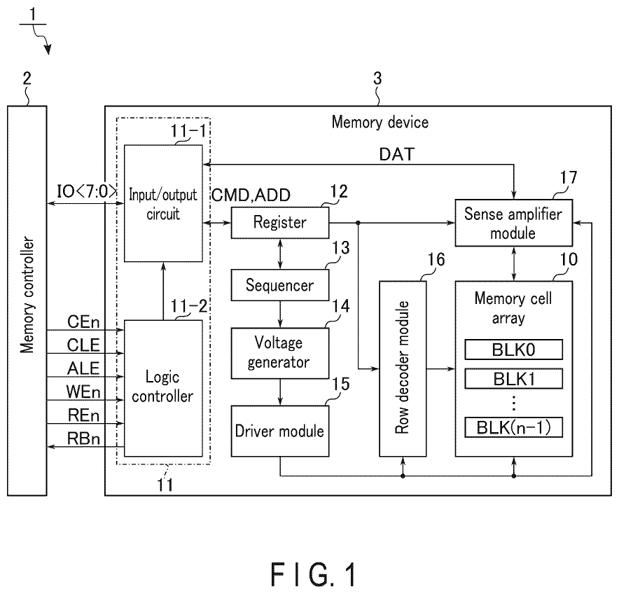

FIG. 1 is a block diagram illustrating an example of a configuration of a memory system including a memory device according to the first embodiment. The memory system is a storage device configured to be connected to an external host (not illustrated). A memory system 1 is, for example, a memory card such as an SD™ card, a universal flash storage (UFS), or a solid state drive (SSD). The memory system 1 includes a memory controller 2 and a memory device 3.

The memory controller 2 includes, for example, an integrated circuit such as a system-on-a-chip (SoC). The memory controller 2 controls the memory device 3 based on a request from the host. Specifically, for example, the memory controller 2 writes data requested to be written by the host to the memory device 3. In addition, the memory controller 2 reads data requested to be read from the host from the memory device 3 and transmits the data to the host.

The memory device 3 is a nonvolatile memory. The memory device 3 is, for example, a NAND flash memory. The memory device 3 stores data in a nonvolatile manner.

Communication between the memory controller 2 and the memory device 3 conforms to, for example, a single data rate (SDR) interface, a toggle double data rate (DDR) interface, or an open NAND flash interface (ONFI).

### 1.1.2 Memory Device

### Overall Configuration

Subsequently, an internal configuration of the memory device according to the first embodiment will be described with reference to the block diagram illustrated in FIG. 1. The memory device 3 includes, for example, a memory cell array 10, an input/output module 11, a register 12, a sequencer 13, a voltage generator 14, a driver module 15, a row decoder module 16, and a sense amplifier module 17.

The memory cell array 10 includes a plurality of blocks BLK0 to BLK(n−1) (n is an integer of 2 or more). The number of blocks BLK included in the memory cell array 10 may be one. The block BLK is a set of a plurality of memory cells. The block BLK is used, for example, as a unit of erasing data. A plurality of bit lines and a plurality of word lines are provided in the memory cell array 10. Each memory cell is associated with, for example, one bit line and one word line. A detailed configuration of the memory cell array 10 will be described later.

The input/output module 11 includes an input/output circuit 11-1 and a logic controller 11-2. The input/output circuit 11-1 and the logic controller 11-2 transmit and receive various signals to and from the memory controller 2. The signal transmitted and received by the input/output circuit 11-1 includes, for example, a signal IO<7:0>. The signals transmitted and received by the logic controller 11-2 include, for example, signals CEn, CLE, ALE, WEn, REn, and RBn. In the present specification, n at the end of the name of the signal means that the signal is asserted in a case where the signal is at a “L (Low)” level.

The signal IO<7:0> is an 8-bit signal. The signal IO<7:0> is an entity of the data DAT transmitted and received between the memory device 3 and the memory controller 2. Hereinafter, the signal IO<7:0> transmitted from the memory controller 2 to the memory device 3 is referred to as an input signal IO<7:0>. The signal IO<7:0> transmitted from the memory device 3 to the memory controller 2 is referred to as an output signal IO<7:0>. The input signal IO<7:0> includes, for example, write data DAT, address information ADD, and a command CMD. The output signal IO<7:0> includes, for example, the read data DAT.

The signal CEn is a signal for enabling the memory device 3.

The signals CLE and ALE are signals for notifying the memory device 3 that the input signals IO<7:0> are a command CMD and an address information ADD, respectively.

The signal WEn is a signal for causing the memory device 3 to take the input signal IO<7:0>.

The signal REn is a signal for reading the output signal IO<7:0> from the memory device 3.

The signal RBn is a signal indicating whether the memory device 3 is in a ready state or a busy state. The ready state is a state in which the memory device 3 can receive a command from the memory controller 2. The busy state is a state in which the memory device 3 cannot receive a command from the memory controller 2. In the signal RBn, the “L” level indicates a busy state.

The input/output circuit 11-1 transmits the address information ADD and the command CMD, and the write data DAT in the input signal IO<7:0> to the register 12 and the sense amplifier module 17, respectively. The input/output circuit 11-1 receives the read data DAT in the output signal IO<7:0> from each of the register 12 and the sense amplifier module 17.

The logic controller 11-2 receives the signals CEn, CLE, ALE, WEn, and REn from the memory controller 2. The logic controller 11-2 transmits the signal RBn to the memory controller 2.

The register 12 stores the address information ADD and the command CMD. The address information ADD includes, for example, a column address, a block address, and a page address. The sequencer 13 controls the entire operation of the memory device 3.

The voltage generator 14 generates a voltage used in a write operation, a read operation, an erase operation, and the like.

The driver module 15 generates a voltage used in a read operation, a write operation, an erase operation, and the like. Then, the driver module 15 applies the generated voltage to a signal line corresponding to a selected word line based on, for example, the page address stored in the register 12.

The row decoder module 16 selects one block BLK in the corresponding memory cell array 10 based on the block address stored in the register 12. Then, the row decoder module 16 transfers, for example, the voltage applied to the signal line corresponding to the selected word line to the selected word line in the selected block BLK.

In the write operation, the sense amplifier module 17 applies a desired voltage to each bit line according to write data DAT received from the memory controller 2. In addition, in the read operation, the sense amplifier module 17 determines the data stored in the memory cell based on the voltage of the bit line, and transfers the determination result to the memory controller 2 as read data DAT.

### Memory Cell Array

Next, a configuration of the memory cell array according to the first embodiment will be described.

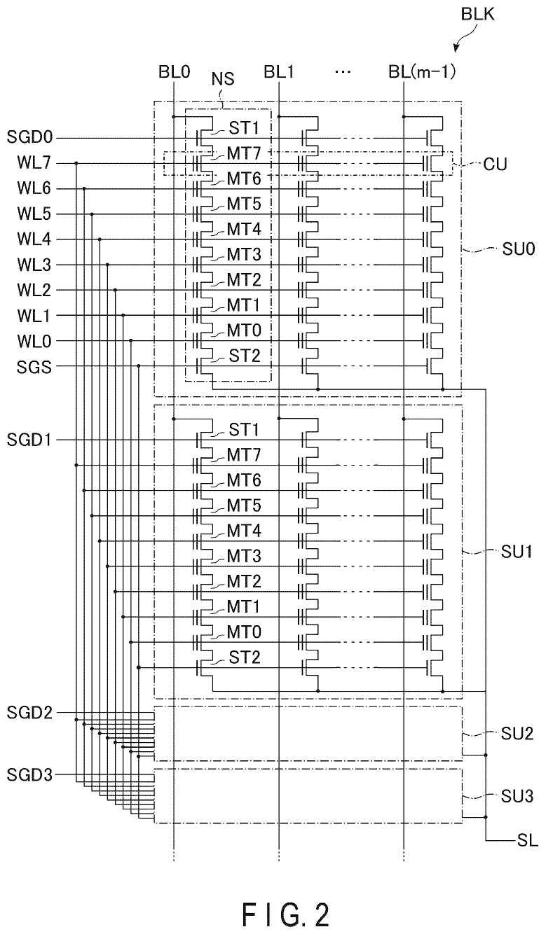

FIG. 2 is a circuit diagram illustrating an example of a circuit configuration of the memory cell array according to the first embodiment. FIG. 2 illustrates one block BLK among the plurality of blocks BLK included in the memory cell array 10. As illustrated in FIG. 2, the block BLK includes, for example, four string units SU0, SU1, SU2, and SU3.

Each of the string units SU0 to SU3 includes a plurality of NAND strings NS respectively associated with bit lines BL0 to BL(m−1) (m is an integer of 2 or more). The number of the bit lines BL may be one. Each NAND string NS includes, for example, memory cell transistors MT0 to MT7 and select transistors ST1 and ST2. Each memory cell transistor MT includes a control gate and a charge storage unit, and stores data in a nonvolatile manner. Each of the select transistors ST1 and ST2 is used to select the string unit SU during various operations.

In each NAND string NS, the memory cell transistors MT0 to MT7 are connected in series. A drain of the select transistor ST1 is connected to the associated bit line BL. A source of the select transistor ST1 is connected to one ends of the memory cell transistors MT0 to MT7 connected in series. A drain of the select transistor ST2 is connected to the other ends of the memory cell transistors MT0 to MT7 connected in series. A source of the select transistor ST2 is connected to a source line SL.

In the same block BLK, control gates of the memory cell transistors MT0 to MT7 are connected to word lines WL0 to WL7, respectively. Gates of the select transistors ST1 in the string units SU0 to SU3 are connected to select gate lines SGD0 to SGD3, respectively. Gates of the select transistors ST2 in the string units SU0 to SU3 are connected to a select gate line SGS.

Different column addresses are allocated to the bit lines BL0 to BL(m−1). Each bit line BL is shared by the NAND string NS to which the same column address is allocated among the plurality of blocks BLK. Each of the word lines WL0 to WL7 is provided for each block BLK. The source line SL is shared among the plurality of blocks BLK, for example.

A set of the memory cell transistors MT connected to the common word line WL in one string unit SU is referred to as, for example, a cell unit CU. For example, a storage capacity of the cell unit CU including the memory cell transistors MT each storing one-bit data is defined as “one-page data”. The cell unit CU may have a storage capacity of two-page data or more according to the number of bits of data stored in the memory cell transistor MT.

Note that a circuit configuration of the memory cell array 10 included in the memory device 3 according to the first embodiment is not limited to the configuration described above. For example, the number of string units SU included in each block BLK can be designed to any number. The number of the memory cell transistors MT and the select transistors ST1 and ST2 included in each NAND string NS can be designed to any number.

### Row Decoder Module

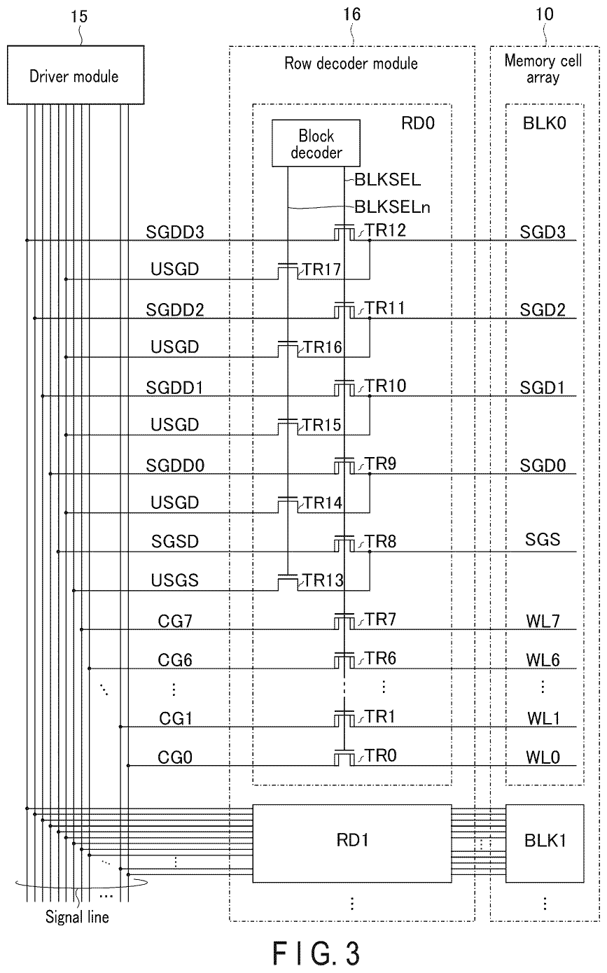

FIG. 3 is a circuit diagram illustrating an example of connection among the memory cell array, the row decoder module, and the driver module according to the first embodiment. As illustrated in FIG. 3, the row decoder module 16 includes a plurality of row decoders RD (RD0, RD1, . . . ). The number of row decoders RD corresponds to the number of blocks BLK. Each of the plurality of row decoders RD has a comparable configuration. In the example of FIG. 3, the configuration of the row decoder RD0 corresponding to the block BLK0 is illustrated. The row decoder RD0 includes a block decoder BD and transistors TR0 to TR17.

Each of the transistors TR0 to TR12 is, for example, an N-type transistor. First ends of the transistors TR0 to TR7 are connected to the block BLK0 through the word lines WL0 to WL7, respectively. Second ends of the transistors TR0 to TR7 are connected to the driver module 15 through wirings CG0 to CG7, respectively. The gates of the transistors TR0 to TR7 are connected to the block decoder BD through a wiring BLKSEL. For example, in the write operation, the

transistors TR0 to TR7 can transfer write voltages to the word lines WL0 to WL7, respectively. The write voltage is a high voltage that can increase a threshold voltage of the memory cell transistor MT. Therefore, the transistors TR0 to TR7 have a withstand voltage high enough to transfer the write voltage. Hereinafter, a transistor having a withstand voltage high enough to transfer a write voltage is also referred to as a “high breakdown voltage transistor” or an “HV transistor”. The HV transistor is designed such that a film thickness of a gate oxide film is at least 10 nm or more, and is, for example, about 40 nm in the case of a transistor that can operate up to 30 V. A transistor having a lower withstand voltage than the HV transistor is also referred to as a “low breakdown voltage transistor” or an “LV transistor”. The LV transistor is designed such that the film thickness of the gate oxide film is, for example, 5 nm or more and 7 nm or less. In addition, a transistor having a lower withstand voltage than the LV transistor is also referred to as a “very-low breakdown voltage transistor” or a “VLV transistor”. The VLV transistor is designed, for example, such that the film thickness of the gate oxide film is 2.5 nm or more and 3.5 nm or less.

The transistor TR8 is, for example, an N-type HV transistor. A first end of the transistor TR8 is connected to the block BLK0 through the select gate line SGS. A second end of the transistor TR8 is connected to the driver module 15 through the wiring SGSD. A gate of the transistor TR8 is connected to the block decoder BD through the wiring BLKSEL.

Each of the transistors TR9 to TR12 is, for example, an N-type HV transistor. First ends of the transistors TR9 to TR12 are connected to the block BLK0 through the select gate lines SGD0 to SGD3, respectively. Second ends of the transistors TR9 to TR12 are connected to the driver module 15 through wirings SGDD0 to SGDD3, respectively. Gates of the transistors TR9 to TR12 are connected to the block decoder BD through the wiring BLKSEL.

The transistor TR13 is, for example, an N-type LV transistor. A first end of the transistor TR13 is connected to the block BLK0 through the select gate line SGS. A second end of the transistor TR13 is connected to the driver module 15 through the wiring USGS. A gate of the transistor TR13 is connected to the block decoder BD through a wiring BLKSELn.

Each of the transistors TR14 to TR17 is, for example, an N-type LV transistor. First ends of the transistors TR14 to TR17 are connected to the block BLK0 through the select gate lines SGD0 to SGD3, respectively. Second ends of the transistors TR14 to TR17 are connected to the driver module 15 through the wiring USGD. Gates of the transistors TR14 to TR17 are connected to the block decoder BD through the wiring BLKSELn.

The block decoder BD supplies voltages at different logic levels to the wirings BLKSEL and BLKSELn. In a case where the block BLK0 is selected, the block decoder BD supplies the “H” level voltage to the wiring BLKSEL, and supplies the “L” level voltage to the wiring BLKSELn. In a case where the block BLK0 is not selected, the block decoder BD supplies the “L” level voltage to the wiring BLKSEL, and supplies the “H” level voltage to the wiring BLKSELn.

### Sense Amplifier Module

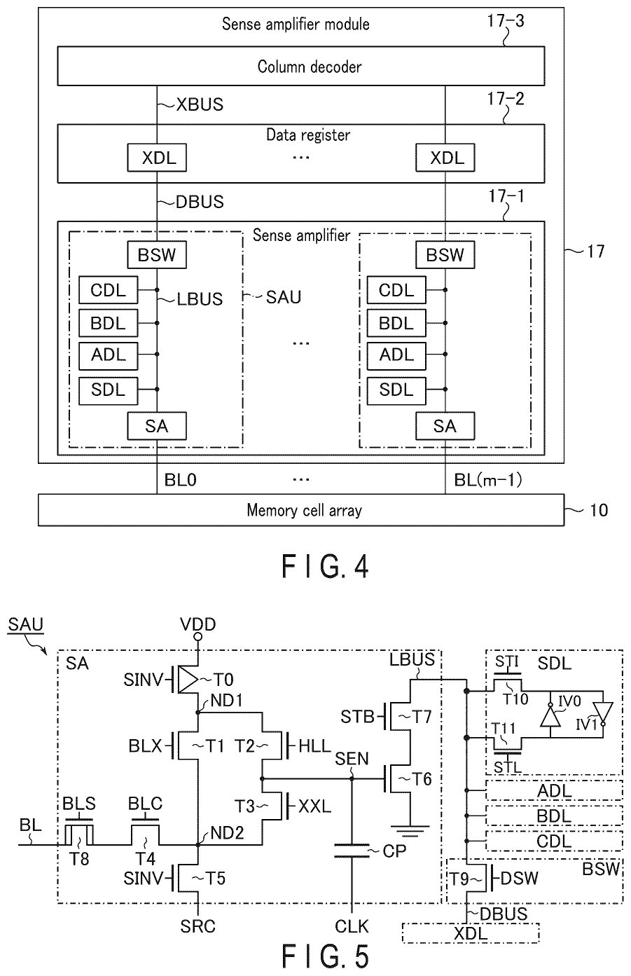

FIG. 4 is a block diagram illustrating an example of connection between the memory cell array and the sense amplifier module according to the first embodiment. As illustrated in FIG. 4, the sense amplifier module 17 includes a sense amplifier 17-1, a data register 17-2, and a column decoder 17-3.

The sense amplifier 17-1 includes a plurality of sense amplifier units SAU provided for each bit line BL. The data register 17-2 includes a plurality of latch circuits XDL provided for each sense amplifier unit SAU.

The sense amplifier unit SAU includes, for example, a sense circuit SA, latch circuits SDL, ADL, BDL, and CDL, and a bus switch BSW. The sense circuit SA, the latch circuits SDL, ADL, BDL, and CDL, and the bus switch BSW are connected through a bus LBUS. The bus switch BSW is connected to a latch circuit XDL through a bus DBUS. The latch circuit XDL, the sense circuit SA, and the latch circuits SDL, ADL, BDL, and CDL are configured to be able to transmit and receive data to and from each other through the bus switch BSW.

During read processing, the sense circuit SA senses a threshold voltage of the memory cell transistor MT through the corresponding bit line BL to determine whether the data stored in the memory cell transistor MT is “0” or “1”. The sense circuit SA applies a voltage to the bit line BL based on write data during write processing.

The latch circuits SDL, ADL, BDL, and CDL temporarily store read data DAT or write data DAT. For example, in the case of the read processing, the read data DAT is stored in any one of the latch circuits SDL, ADL, BDL, and CDL. Furthermore, for example, in the case of the write processing, the write data DAT of the latch circuit XDL is stored in any of the latch circuits SDL, ADL, BDL, and CDL.

The bus switch BSW is a switch that controls transmission and reception of data between the sense amplifier 17-1 and the data register 17-2.

The latch circuit XDL is used as a cache memory between the sense amplifier unit SAU and the column decoder 17-3. More specifically, the write data DAT received from the column decoder 17-3 is transmitted to the latch circuits SDL, ADL, BDL, and CDL or the sense circuit SA through the latch circuit XDL. In addition, the read data DAT stored in the latch circuits SDL, ADL, BDL, and CDL or the sense circuit SA is transmitted to the column decoder 17-3 through the latch circuit XDL.

The column decoder 17-3 is connected to a plurality of corresponding latch circuits XDL through a plurality of buses XBUS. The column decoder 17-3 receives the write data DAT from the input/output module 11 during the write processing. Then, the column decoder 17-3 transmits the write data DAT to the latch circuit XDL corresponding to the column address. In addition, the column decoder 17-3 receives the read data DAT from the latch circuit XDL corresponding to the column address during the read processing. Then, the column decoder 17-3 transmits the read data DAT to the input/output module 11.

FIG. 5 is a circuit diagram illustrating an example of a configuration of the sense amplifier module according to the first embodiment. As illustrated in FIG. 5, the sense circuit SA in the sense amplifier unit SAU includes nine transistors T0 to T8 and a capacitor CP. The bus switch BSW includes a transistor T9. The latch circuit SDL includes transistors T10 and T11 and inverters IV0 and IV1. The transistor T0 is, for example, a P-type LV transistor. The transistors T1 to T7 and T9 are, for example, N-type LV transistors. The transistor T8 is, for example, an N-type HV transistor. The transistors T10 and T11 are, for example, N-type LV transistors or VLV transistors. Although not illustrated in FIG. 5, the latch circuits ADL, BDL, CDL, and XDL have the comparable configuration as the latch circuit SDL.

A power supply voltage VDD is supplied to a first end of the transistor T0. A second end of the transistor T0 is connected to a node ND1. A control end of the transistor T0 is connected to a node SINV.

A first end of the transistor T1 is connected to the node ND1. A second end of the transistor T1 is connected to a node ND2. A control end of the transistor T1 is connected to a node BLX.

A first end of the transistor T2 is connected to the node ND1. A second end of the transistor T2 is connected to a node SEN. A control end of the transistor T2 is connected to a node HLL.

A first end of the transistor T3 is connected to the node SEN. A second end of the transistor T3 is connected to the node ND2. A control end of the transistor T3 is connected to a node XXL.

A first end of the transistor T4 is connected to the node ND2. A second end of the transistor T4 is connected to a first end of the transistor T8. A second end of the transistor T8 is connected to the bit line BL. A control end of the transistor T4 is connected to a node BLC. A control end of the transistor T8 is connected to a node BLS.

A first end of the transistor T5 is connected to the node ND2. A second end of the transistor T5 is connected to a node SRC. A control end of the transistor T5 is connected to a node SINV.

A first end of the transistor T6 is grounded. A second end of the transistor T6 is connected to a first end of the transistor T7. A second end of the transistor T7 is connected to a bus LBUS. A control end of the transistor T6 is connected to the node SEN. A control end of the transistor T7 is connected to a node STB.

A first end of the capacitor CP is connected to the node SEN. A clock signal CLK is supplied to a second end of the capacitor CP.

A first end of the transistor T9 is connected to the bus LBUS. A second end of the transistor T9 is connected to a bus DBUS.

A first end of the transistor T10 and a first end of the transistor T11 are connected to the bus LBUS. A second end of the transistor T10 is connected to an output end of the inverter IV0 and an input end of the inverter IV1. A second end of the transistor T11 is connected to an input end of the inverter IV0 and an output end of the inverter IV1.

With the above configuration, the sense circuit SA can determine the data stored in the memory cell transistor MT based on the voltage of the node SEN during the read processing. As a result of the determination, the data read by the node SEN is transferred to the latch circuits SDL, ADL, BDL, and CDL. In addition, the data transferred to the latch circuits SDL, ADL, BDL, and CDL is transferred to the latch circuit XDL through the bus switch BSW.

### 1.2 Structure

Next, a structure of the memory device according to the first embodiment will be described.

Hereinafter, a direction in which the word line WL extends is referred to as an X direction. A direction in which the bit line BL extends is defined as a Y direction. A direction intersecting a plane (XY plane) including the X direction and the Y direction is defined as a Z direction. Of the Z direction, a direction from the word line WL to the bit line BL is defined as a Z1 direction. A direction from the bit line BL to the word line WL is defined as a Z2 direction.

### 1.2.1 Memory Cell Array

First, a detailed structure of the memory cell array 10 will be described.

### Overall Planar Layout

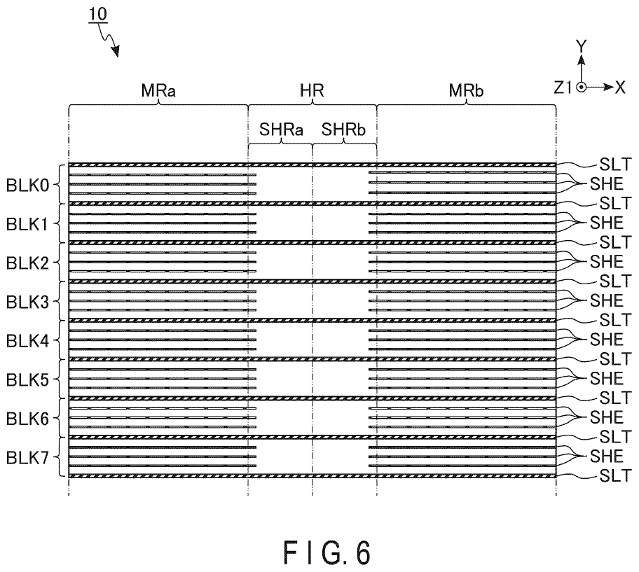

FIG. 6 is a plan view illustrating an example of a planar layout of the memory cell array according to the first embodiment. FIG. 6 illustrates a case where the memory cell array 10 includes eight blocks BLK0 to BLK7.

As illustrated in FIG. 6, the memory cell array includes memory regions MRa and MRb and a hookup region HR arranged in the X direction. The memory regions MRa and MRb are regions in which the memory cell transistor MT is provided. The hookup region HR is a region where contacts for electrically connecting the word lines WL0 to WL7 and the select gate lines SGS and SGD to the row decoder module 16 are provided. The hookup region HR is located between the memory region MRa and the memory region MRb.

Each of the plurality of blocks BLK extends in the X direction so as to cross the memory region MRa, the hookup region HR, and the memory region MRb. The plurality of blocks BLK is arranged in the Y direction. The memory cell array 10 includes, for example, a plurality of slits SLT and a plurality of slits SHE.

Each slit SLT extends in the X direction so as to cross the memory region MRa, the hookup region HR, and the memory region MRb. The plurality of slits SLT is arranged in the Y direction. Each slit SLT has, for example, a structure in which an insulator is embedded. Each slit SLT divides adjacent wirings (for example, the word lines WL0 to WL7 and the select gate lines SGD and SGS) through the slit SLT. In the memory cell array 10, each of the regions partitioned by the slits SLT corresponds to one block BLK.

The plurality of slits SHE includes a plurality of slits SHE arranged in the Y direction in the memory region MRa and a plurality of slits SHE arranged in the Y direction in the memory region MRb. Each slit SHE located in the memory region MRa extends in the X direction so as to cross the memory region MRa. Each slit SHE located in the memory region MRb extends in the X direction so as to cross the memory region MRb. In the example of FIG. 6, in each of the memory regions MRa and MRb, three slits SHE are arranged between two slits SLT adjacent in the Y direction. Each slit SHE has, for example, a structure in which an insulator is embedded. Each slit SHE divides the adjacent wirings (at least select gate line SGD) through the slit SHE. In the memory cell array 10, each of regions divided by a pair of adjacent slits SLT and SHE or a pair of adjacent two slits SHE corresponds to one string unit SU.

The hookup region HR includes sub-hookup regions SHRa and SHRb divided in two and arranged in the X direction. The sub-hookup region SHRa is adjacent to the memory region MRa. The sub-hookup region SHRb is adjacent to the memory region MRb. The stacked wirings of each block BLK are connected to the row decoder module 16 through, for example, contacts arranged in the sub-hookup region SHRa or SHRb. Hereinafter, a case where each stacked wirings of the blocks BLK(i*4) and BLK(i*4+3) (“i” is an integer of 0 or more) are connected to the contacts provided in the sub-hookup region SHRa, and each stacked wirings of the blocks BLK(i*4+1) and BLK(i*4+2) are connected to the contacts provided in the sub-hookup region SHRb will be described. In this case, in the hookup region HR, the structures of the portions corresponding to the blocks BLK0 to BLK3 are repeatedly arranged in the Y direction.

The planar layout of the memory cell array 10 may be another layout. For example, the number of slits SHE disposed between two adjacent slits SLT can be designed to be any number. The number of string units SU included in each block BLK can be changed based on the number of slits SHE arranged between two adjacent slits SLT.

### Planar Layout in Memory Region

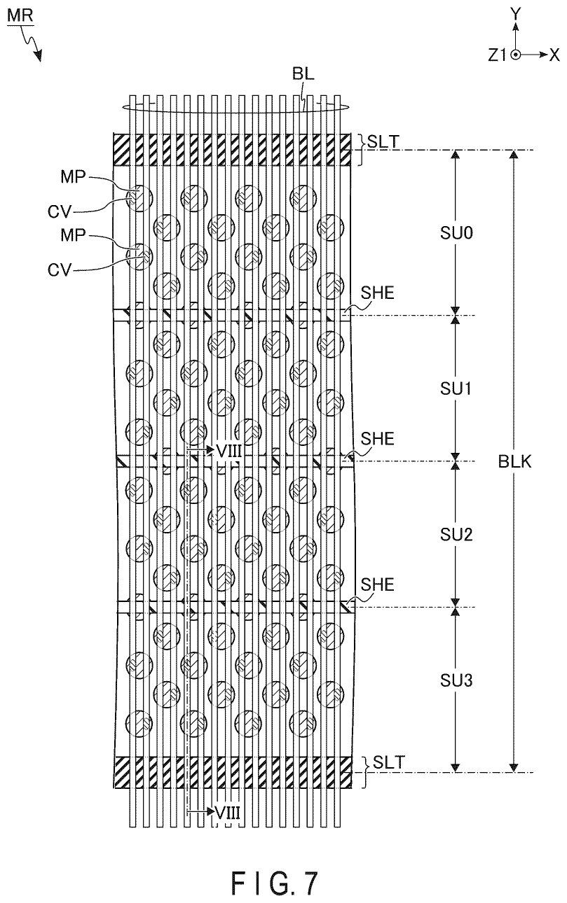

FIG. 7 is a plan view illustrating an example of a planar layout in the memory region MR of the memory cell array according to the first embodiment. FIG. 7 illustrates a region including one block BLK (string units SU0 to SU3). As illustrated in FIG. 7, the memory device 3 includes, for example, a plurality of memory pillars MP, a plurality of contacts CV, and a plurality of bit lines BL in the memory region MR.

Each memory pillar MP functions as one NAND string NS. The plurality of memory pillars MP is arranged in a staggered manner of, for example, 19 rows in a region between two adjacent slits SLT. For example, one slit SHE is arranged to overlap each of the memory pillar MP of the fifth column, the memory pillar MP of the tenth column, and the memory pillar MP of the fifteenth column when counted from the upper side of the paper surface.

The plurality of bit lines BL is arranged in the X direction. Each bit line BL is arranged so as to overlap at least one memory pillar MP for each string unit SU. In the example of FIG. 7, two bit lines BL are arranged to overlap one memory pillar MP. The memory pillar MP is electrically connected to one bit line BL among the plurality of bit lines BL arranged in an overlapping manner through the contact CV. Note that the contact CV between the memory pillar MP in contact with the two different select gate lines SGD and the bit line BL (that is, the contact CV disposed so as to overlap with the slit SHE) can be omitted.

Note that the planar layout in the memory region MR may be another layout. For example, the number and arrangement of the memory pillars MP and the slits SHE arranged between two adjacent slits SLT can be appropriately changed. The number of bit lines BL overlapping each memory pillar MP can be designed to an arbitrary number.

### Cross-sectional Structure in Memory Region

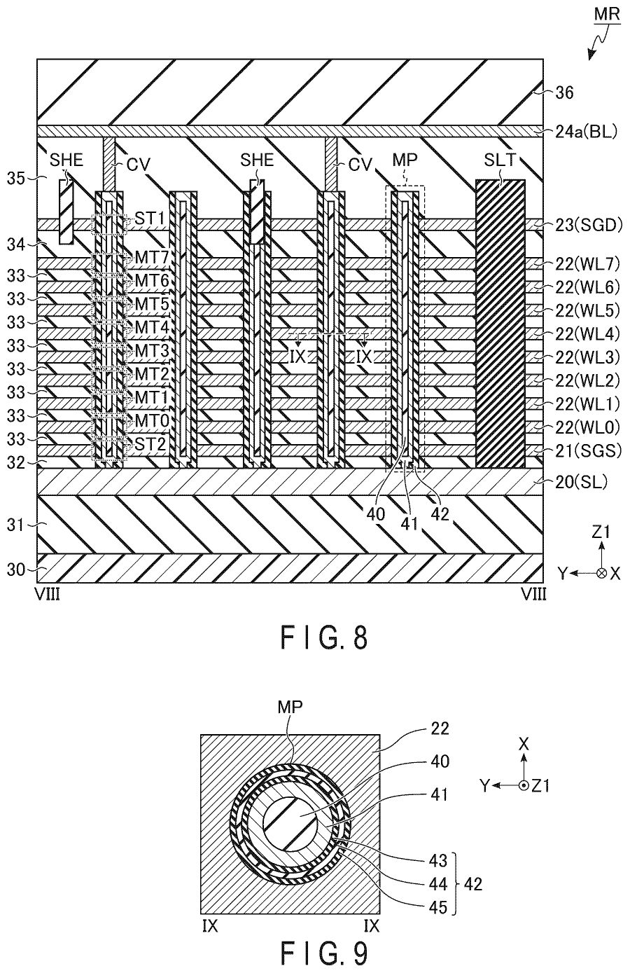

FIG. 8 is a cross-sectional view taken along a line VIII-VIII of FIG. 7, illustrating an example of a cross-sectional structure in the memory region MR of the memory cell array according to the first embodiment. As illustrated in FIG. 8, in the memory region MR, the memory cell array 10 includes, for example, a semiconductor layer 20, conductive layers 21, 22, 23, and 24a, and insulating layers 31, 32, 33, 34, 35, and 36. The insulating layers 31 to 36 include, for example, silicon oxide. In FIG. 8, the Z1 direction corresponds to the upper side of the paper surface.

The semiconductor layer 20 is provided on the insulating layer 31. The semiconductor layer 20 is formed in, for example, a plate shape extending along the XY plane. The semiconductor layer 20 includes, for example, silicon and is used as the source line SL.

The insulating layer 32 is provided on the semiconductor layer 20. The conductive layer 21 is provided on the insulating layer 32. The conductive layer 21 is formed in, for example, a plate shape extending along the XY plane. The conductive layer 21 includes, for example, tungsten and is used as the select gate line SGS.

A plurality of insulating layers 33 and conductive layers 22 are alternately provided on the conductive layer 21. The plurality of conductive layers 22 is formed in, for example, a plate shape extending along the XY plane. The plurality of conductive layers 22 includes, for example, tungsten, and is used as the word lines WL0 to WL7, respectively, in order from the bottom.

The insulating layer 34 is provided on the uppermost conductive layer 22. The conductive layer 23 is provided on the insulating layer 34. The conductive layer 23 is formed in, for example, a plate shape extending along the XY plane. The conductive layer 23 includes, for example, tungsten and is used as the select gate line SGD.

The insulating layer 35 is provided on the conductive layer 23. The conductive layer 24a is provided on the insulating layer 35. The upper surface of the conductive layer 24a is covered with the insulating layer 36. The conductive layer 24a is formed in, for example, a line shape extending in the Y direction. The conductive layer 24a includes, for example, copper and is used as the bit line BL.

The slit SLT has a plate-like portion extending along the XZ plane. The slit SLT divides the insulating layers 32 to 34 and the conductive layers 21 to 23. Each memory pillar MP extends in the Z direction and penetrates the insulating layers 32 to 34 and the conductive layers 21 to 23. Each memory pillar MP includes, for example, a core film 40, a semiconductor film 41, and a stacked film 42. The core film 40 is an insulator extending in the Z direction. The semiconductor film 41 covers the core film 40. A lower portion of the semiconductor film 41 is in contact with the semiconductor layer 20. The stacked film 42 covers a side surface of the semiconductor film 41. The contact CV is provided on an upper surface of the semiconductor film 41. The semiconductor film 41 and the conductive layer 24a are connected through the contact CV.

Note that a contact CV corresponding to one memory pillar MP of the two memory pillars MP is illustrated in the illustrated region. The contact CV is connected in a region (not illustrated) to the memory pillar MP to which the contact CV is not connected in the region. A portion where the memory pillar MP intersects the conductive layer 21 functions as the select transistor ST2. A portion where the memory pillar MP intersects the conductive layer 22 functions as the memory cell transistor MT. A portion where the memory pillar MP intersects the conductive layer 23 functions as the select transistor ST1.

FIG. 9 is a cross-sectional view taken along a line IX-IX of FIG. 8, illustrating an example of a cross-sectional structure of the memory pillar according to the first embodiment. FIG. 9 illustrates a cross section including the memory pillar MP and the conductive layer 22 and parallel to the surface of the source line SL. As illustrated in FIG. 9, the stacked film 42 includes, for example, a tunnel insulating film 43, a charge storage film 44, and a block insulating film 45.

The core film 40 is provided, for example, in a central portion of the memory pillar MP. The semiconductor film 41 surrounds a side surface of the core film 40. The tunnel insulating film 43 surrounds a side surface of the semiconductor film 41. The charge storage film 44 surrounds a side surface of the tunnel insulating film 43. The block insulating film 45 surrounds a side surface of the charge storage film 44. The conductive layer 22 surrounds a side surface of the block insulating film 45. The semiconductor film 41 is used as a channel (current path) of the memory cell transistors MT0 to MT7 and the select transistors ST1 and ST2. Each of the tunnel insulating film 43 and the block insulating film 45 includes, for example, silicon oxide. The charge storage film 44 includes, for example, silicon nitride. As a result, each of the memory pillars MP functions as one NAND string NS.

### Planar Layout in Hookup Region

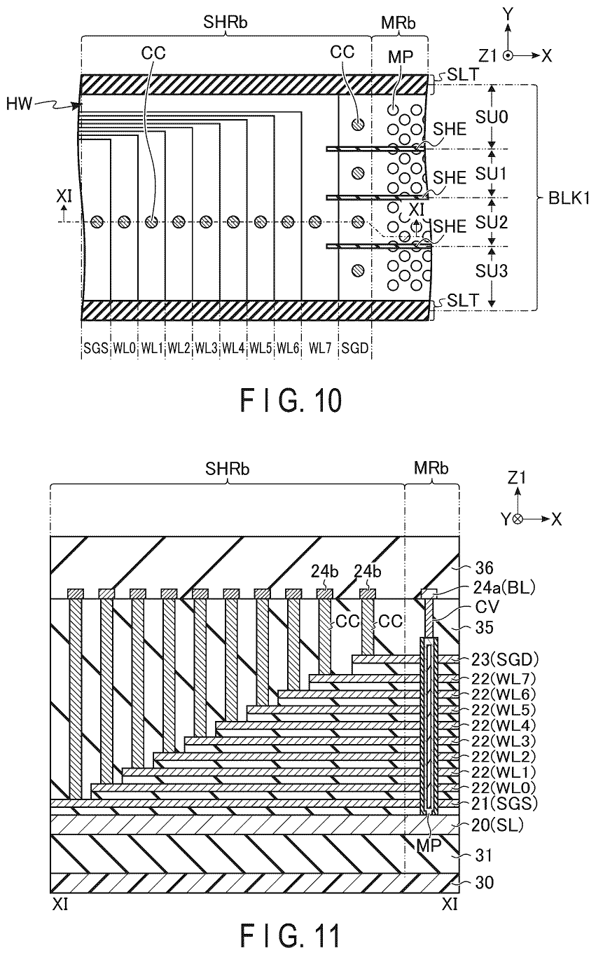

FIG. 10 is a plan view illustrating an example of a planar layout in the hookup region of the memory cell array according to the first embodiment. In FIG. 10, a portion corresponding to the block BLK1 and corresponding to the sub-hookup region SHRb in the hookup region HR and a part of the memory region MRb are extracted and illustrated. As illustrated in FIG. 10, in the sub-hookup region SHRb, the stacked wiring (select gate line SGS, word lines WL0 to WL7, and select gate line SGD) of the block BLK1 has a terrace portion that does not overlap with the stacked wiring of an upper layer as viewed in the Z1 direction. In addition, the memory cell array 10 includes a plurality of contacts CC in the sub-hookup region SHRb.

The terrace portion configures a staircase structure having a step in the X direction. Specifically, in the hookup region HR, steps are formed along the X direction between the select gate line SGS and the word line WL0, between the word line WL0 and the word line WL1, . . . , between the word line WL6 and the word line WL7, and between the word line WL7 and the select gate line SGD. The select gate line SGS and the word lines WL0 to WL7 of the memory regions MRa and the select gate line SGS and the word lines WL0 to WL7 of the memory regions MRb are continuously provided through a highway portion HW in the hookup region HR. The highway portion HW corresponds to a portion of the conductive layer continuously provided between the memory regions MRa and MRb along the slit SLT.

The contact CC is a conductor used for connection between the row decoder module 16 and the stacked wiring. The plurality of contacts CC associated with the block BLK1 is respectively connected to the terrace portions of the select gate lines SGS and SGD and the word lines WL0 to WL7 provided in the sub-hookup region SHRb. In a case where the select gate line SGD in the memory region MRa and the select gate line SGD in the memory region MRb are associated with the same string unit SU, for example, the select gate lines SGD are short-circuited through the contact CC and the upper wiring layer.

Note that the layout of the portion where the sub-hookup region SHRa and the block BLK0 overlap is similar to a layout in which the layout of the portion where the sub-hookup region SHRb and the block BLK1 overlap is inverted in each of the X direction and the Y direction. Further, the layout of the portion where the hookup region HR and the blocks BLK2 and BLK3 overlap is similar to a layout in which the layout of the portion where the hookup region HR and the blocks BLK0 and BLK1 overlap is inverted in the Y direction. The present invention is not limited thereto, and the planar layout of the hookup region HR can be appropriately changed.

### Cross-sectional Structure in Hookup Region

FIG. 11 is a cross-sectional view taken along a line XI-XI of FIG. 10, illustrating an example of a cross-sectional structure in the hookup region of the memory cell array according to the first embodiment. As illustrated in

FIG. 11, the memory cell array 10 includes, for example, a plurality of conductive layers 24b in the sub-hookup region SHRb. In FIG. 11, the Z1 direction corresponds to the upper side of the paper surface.

In the sub-hookup region SHRb, ends of the conductive layers 21 to 23 in the X direction are provided in a stepwise manner and covered with the insulating layer 35. The insulating layer 36 is also provided in the sub-hookup region SHRb similarly to the memory region MR.

The plurality of contacts CC is provided on the upper surface of the terrace portion of each of the select gate line SGS, the word lines WL0 to WL7, and the select gate line SGD. Each contact CC penetrates the insulating layer 35. One conductive layer 24b is provided on the upper surface of each of the plurality of contacts CC. The conductive layer 24b is located in the same layer as the conductive layer 24a.

A set of the conductive layer 24b and the contact CC corresponds to a wiring and a contact for connecting one of the conductive layers 21 to 23 and the row decoder module 16. Although not illustrated, each of the conductive layers 22 and 23 is similarly connected to the row decoder module 16 through the associated set of the conductive layer 24b and the contact CC.

### 1.2.2 Memory Device

Next, a detailed structure of the memory device 3 will be described.

### Bonded Structure and Planar Layout

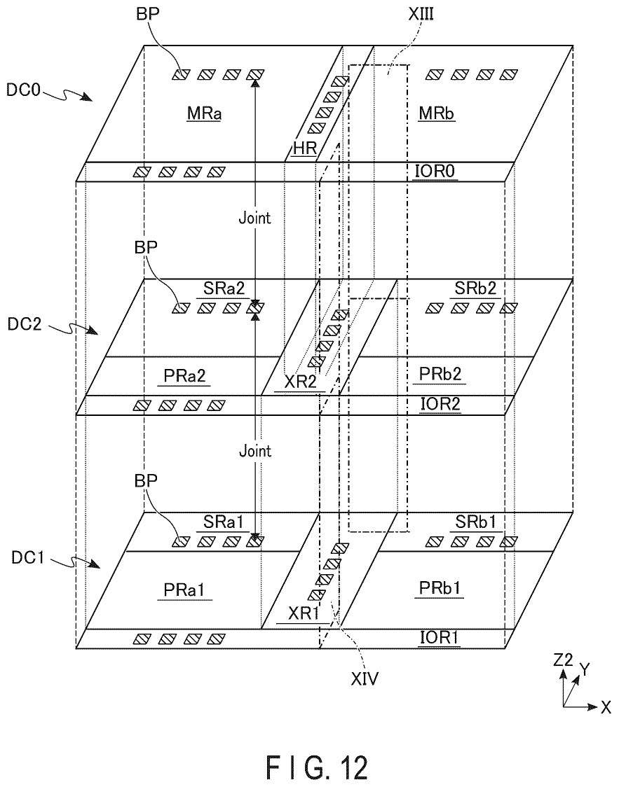

FIG. 12 is a perspective view illustrating an example of a bonded structure of the memory device and a planar layout of each chip according to the first embodiment. In FIG. 12, the Z2 direction corresponds to the upper side of the paper surface.

As illustrated in FIG. 12, the memory device 3 has, for example, a structure in which a circuit chip DC1, a circuit chip DC2, and a memory chip DC0 are stacked in this order from the bottom. The circuit chip DC1 and the circuit chip DC2, and the circuit chip DC2 and the memory chip DC0 are bonded by a plurality of joint pads BP.

The circuit chips DC1 and DC2 include CMOS circuits. In the circuit chip DC1, an LV transistor and a VLV transistor are mainly formed. In the circuit chip DC2, an HV transistor and an LV transistor are mainly formed. In the memory chip DC0, a memory cell transistor MT is formed.

For example, the memory chip DC0 further includes an input/output region IOR0 in addition to the above-described memory regions MRa and MRb and the hookup region HR as viewed in the Z direction. The input/output region IOR0 is a region in which a circuit, wiring, and the like for supplying a power supply voltage and the like to the memory chip DC0 are formed. The input/output region IOR0 is aligned in the Y direction with the memory regions MRa and MRb and the hookup region HR.

The circuit chip DC1 is divided into, for example, a transfer region XR1, sense regions SRa1 and SRb1, peripheral circuit regions PRa1 and PRb1, and an input/output region IOR1 as viewed in the Z direction.

The transfer region XR1 is a region in which the LV transistor and the VLV transistor configuring the row decoder module 16 are arranged. The transfer region XR1 is arranged so as to overlap the entire hookup region HR, a portion of the memory region MRa adjacent to the hookup region HR, and a portion of the memory region MRb adjacent to the hookup region HR as viewed in the Z direction. That is, a length of the transfer region XR1 in the X direction is longer than a length of the hookup region HR in the X direction.

The sense regions SRa1 and SRb1 are regions in which the LV transistor and the VLV transistor configuring the sense amplifier module 17 are arranged. The sense regions SRa1 and SRb1 sandwich the transfer region XR1 in the X direction. The sense regions SRa1 and SRb1 are arranged so as to overlap the memory regions MRa and MRb, respectively, as viewed in the Z direction.

The peripheral circuit regions PRa1 and PRb1 are regions in which the LV transistors and the VLV transistors configuring the register 12, the sequencer 13, the voltage generator 14, and the driver module 15 are arranged. The peripheral circuit regions PRa1 and PRb1 sandwich the transfer region XR1 in the X direction. The peripheral circuit regions PRa1 and PRb1 are aligned in the Y direction with the sense regions SRa1 and SRb1, respectively. The peripheral circuit regions PRa1 and PRb1 are arranged so as to overlap the memory regions MRa and MRb, respectively, as viewed in the Z direction. The input/output region IOR1 is a region where a

circuit, wiring, and the like for supplying a power supply voltage and the like to the circuit chip DC1 are formed. The input/output region IOR1 is aligned in the Y direction with the peripheral circuit regions PRa1 and PRb1 and the transfer region XR1. The input/output region IOR1 is arranged so as to overlap the input/output region IOR0 as viewed in the Z direction.

For example, as viewed in the Z direction, the circuit chip DC2 is divided into a transfer region XR2, sense regions SRa2 and SRb2, peripheral circuit regions PRa2 and PRb2, and an input/output region IOR2.

The transfer region XR2 is a region where the HV transistor and the LV transistor configuring the row decoder module 16 are arranged. The transfer region XR2 is arranged so as to overlap the entire hookup region HR, a portion of the memory region MRa adjacent to the hookup region HR, and a portion of the memory region MRb adjacent to the hookup region HR as viewed in the Z direction. That is, a length of the transfer region XR2 in the X direction is longer than a length of the hookup region HR in the X direction.

The sense regions SRa2 and SRb2 are regions where the HV transistor and the LV transistor configuring the sense amplifier module 17 are arranged. The sense regions SRa2 and SRb2 sandwich the transfer region XR2 in the X direction. The sense regions SRa2 and SRb2 are arranged so as to overlap the memory regions MRa and MRb, respectively, as viewed in the Z direction.

The peripheral circuit regions PRa2 and PRb2 are regions in which the HV transistors and the LV transistors configuring the register 12, the sequencer 13, the voltage generator 14, and the driver module 15 are arranged. The peripheral circuit regions PRa2 and PRb2 sandwich the transfer region XR2 in the X direction. The peripheral circuit regions PRa2 and PRb2 are aligned in the Y direction with the sense regions SRa2 and SRb2, respectively. The peripheral circuit regions PRa2 and PRb2 are arranged so as to overlap the memory regions MRa and MRb, respectively, as viewed in the Z direction.

The input/output region IOR2 is a region where a circuit, wiring, and the like for supplying a power supply voltage and the like to the circuit chip DC2 are formed. The input/output region IOR2 is aligned in the Y direction with the peripheral circuit regions PRa2 and PRb2 and the transfer region XR2. The input/output region IOR2 is arranged so as to overlap the input/output regions IOR0 and IOR1 as viewed in the Z direction.

### Cross-Sectional Structure

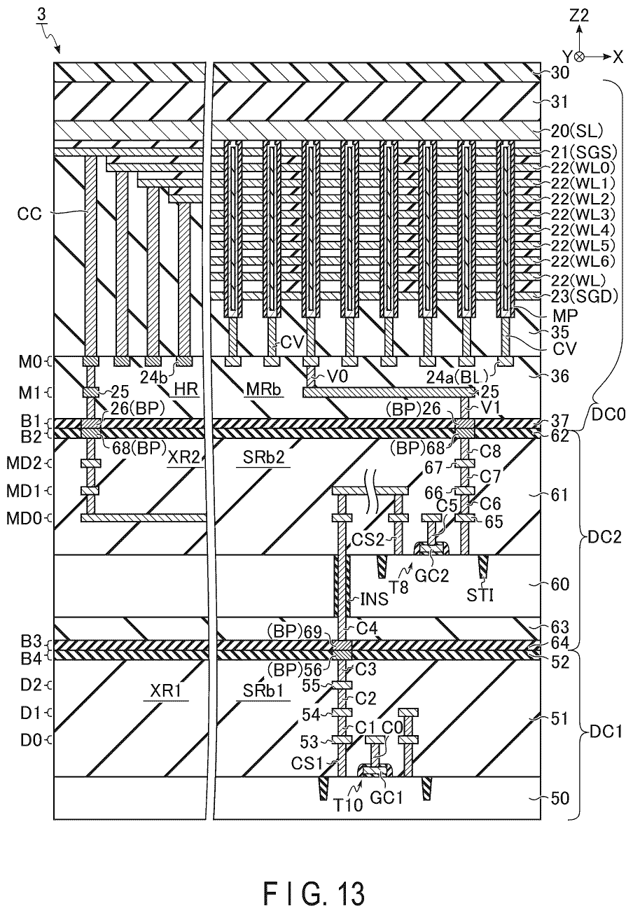

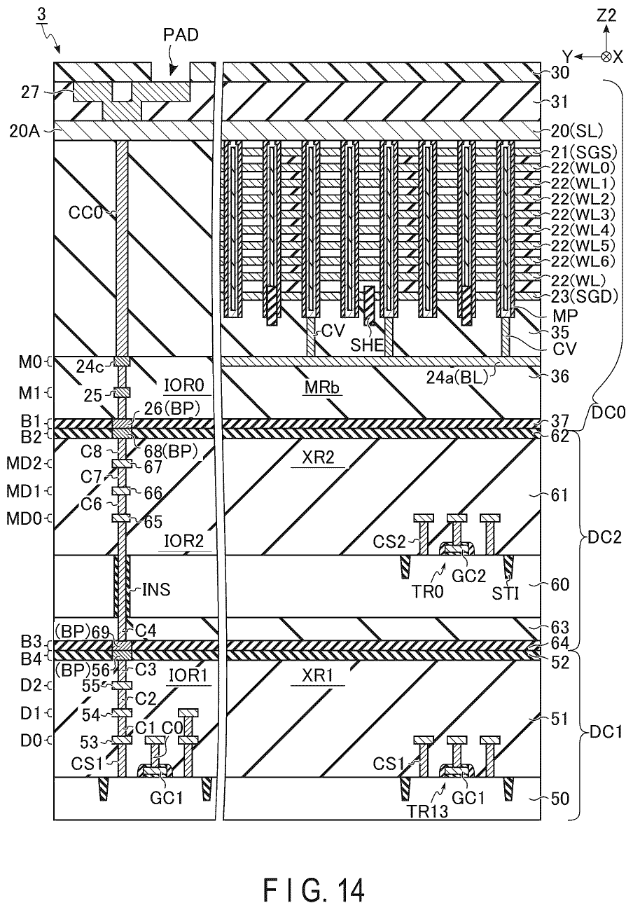

FIG. 13 is a cross-sectional view taken along a plane XIII of FIG. 12, illustrating an example of a cross-sectional structure of the memory device according to the first embodiment. FIG. 14 is a cross-sectional view taken along a plane XIV of FIG. 12, illustrating an example of a cross-sectional structure of the memory device according to the first embodiment. The plane XIII is a plane including the memory region MRb and the hookup region HR of the memory chip DC0, the sense region SRb1 and the transfer region XR1 of the circuit chip DC1, and the sense region SRb2 and the transfer region XR2 of the circuit chip DC2. The plane XIV is a plane including the memory region MRb and the input/output region IOR0 of the memory chip DC0, the transfer region XR1 and the input/output region IOR1 of the circuit chip DC1, and the transfer region XR2 and the input/output region IOR2 of the circuit chip DC2.

As illustrated in FIGS. 13 and 14, the memory device 3 includes a surface passivation layer 30, insulating layers 31 and 37, a semiconductor layer 20A, conductive layers 25, 26, and 27, and contacts CC0, V0, and V1 in the memory chip DC0. The memory device 3 includes a substrate 50, insulating layers 51 and 52, conductive layers GC1 and 53 to 56, and contacts CS1 and C0 to C3 in the circuit chip DC1. The memory device 3 includes a substrate 60, insulating layers 61 to 64, conductive layers GC2 and 65 to 69, and contacts CS2 and C4 to C8 in the circuit chip DC2.

In the input/output region IOR0, the semiconductor layer 20A is provided in the same layer as the semiconductor layer 20. The semiconductor layer 20A is electrically insulated from the semiconductor layer 20. The conductive layer 27 is provided on the semiconductor layer 20A on a side opposite to the memory cell array 10 with respect to the semiconductor layer 20A. A part of the conductive layer 27 is exposed on a surface of the memory device 3 and is used as the input/output pad PAD.

The insulating layer 31 is provided on the semiconductor layer 20 on a side opposite to the memory cell array 10 with respect to the semiconductor layer 20. The conductive layer 27 is provided in the insulating layer 31. The surface passivation layer 30 is provided on the insulating layer 31. The surface passivation layer 30 is a layer corresponding to the surface of the memory device 3, and includes, for example, a resin material such as polyimide. In the input/output region IOR0, a part of the surface passivation layer 30 is removed. The conductive layer 27 is exposed from a portion from which the surface passivation layer 30 is removed.

The contact CC0 is provided on the semiconductor layer 20A on the memory cell array 10 side with respect to the semiconductor layer 20A. A conductive layer 24c is provided on the contact CC0. The conductive layer 24c is provided in the same layer as the conductive layers 24a and 24b. Hereinafter, a layer having a height at which the conductive layers 24a and 24b are provided is referred to as a wiring layer M0.

The contact V0 is provided on each of the conductive layer 24a, the conductive layer 24b, and the conductive layer 24c. The conductive layer 25 is provided on the contact V0. The conductive layer 25 extends in a direction (for example, in the X direction) intersecting the conductive layer 24 in the XY plane. The contact V1 is provided on the conductive layer 25. The conductive layer 26 is provided on the contact V1. That is, the contacts V0 and V1 are arranged so as not to overlap each other as viewed in the Z direction. Therefore, the conductive layer 26 is disposed at a position shifted in the X direction with respect to the corresponding conductive layer 24a as viewed in the Z direction.

The contact V0, the conductive layer 25, and the contact V1 are covered with the insulating layer 36. The insulating layer 37 is provided on the insulating layer 36. The conductive layer 26 is provided in the insulating layer 37. The insulating layer 37 is, for example, a silicon oxide film.

Hereinafter, a layer having a height at which the conductive layer 25 is provided is referred to as a wiring layer M1. A layer having a height at which the conductive layer 26 and the insulating layer 37 are provided is referred to as a joint layer B1.

The substrate 50 is a silicon substrate. The substrate 50 has a thickness of, for example, about 1 micrometer (μm).

The insulating layer 51 is provided on the substrate 50. The insulating layer 51 covers a circuit (for example, the conductive layers 53 to 55 and the contacts CS1 and C0 to C3) provided on the substrate 50. The insulating layer 51 can include a plurality of insulating layers. Furthermore, the insulating layer 51 includes wiring layers D0, D1, and D2 in this order from the substrate 50 side. A wiring of the circuit chip DC1 is provided in the wiring layers D0, D1, and D2.

The insulating layer 52 is provided on the insulating layer 51. The insulating layer 52 is in contact with the insulating layer 64 included in the circuit chip DC2. A boundary between the insulating layer 52 and the insulating layer 64 corresponds to a joint surface between the circuit chip DC1 and the circuit chip DC2. The insulating layer 52 is, for example, a silicon oxide film. Hereinafter, the layer including the insulating layer 52 is referred to as a joint layer B4.

The substrate 60 is a silicon substrate. The substrate 60 may have a thickness of, for example, about 10 μm. Note that the thickness of the substrate 60 is preferably as thin as possible from the viewpoint of ease of processing of a through-via responsible for electrical connection between the circuit chips DC1 and DC2. Therefore, the substrate 60 may have a thickness (that is, about 1 μm) comparable with that of the substrate 50.

The insulating layer 61 is provided on the substrate 60. The insulating layer 61 covers a circuit (for example, the conductive layer 65 to 67, a part of the contact C4, and the contacts CS2 and C5 to C8) provided on the substrate 60. The insulating layer 61 can include a plurality of insulating layers. Furthermore, the insulating layer 61 includes wiring layers MD0, MD1, and MD2 in this order from the substrate 60 side. A wiring of the circuit chip DC2 is provided in the wiring layers MD0, MD1, and MD2.

The insulating layer 62 is provided on the insulating layer 61. The insulating layer 62 is in contact with the insulating layer 37 included in the memory chip DC0. A boundary between the insulating layer 62 and the insulating layer 37 corresponds to a joint surface between the circuit chip DC2 and the memory chip DC0. The insulating layer 62 is, for example, a silicon oxide film. Hereinafter, the layer including the insulating layer 62 is referred to as a joint layer B2. The joint layer B2 is in contact with the joint layer B1.

The insulating layer 63 is provided on the substrate 60 on a side opposite to the insulating layer 61 with respect to the substrate 60. The insulating layer 64 is provided on the insulating layer 63. Hereinafter, the layer including the insulating layer 64 is referred to as a joint layer B3. The joint layer B3 is in contact with the joint layer B4.

The conductive layer GC1 is provided on a gate insulating film provided on the substrate 50. The conductive layer GC1 in the sense region SRb1 is used as, for example, gate electrodes of the LV transistor and the VLV transistor (for example, transistor T10) included in the sense amplifier module 17. The conductive layer GC1 in the transfer region XR1 is used, for example, as gate electrodes of the LV transistor and the VLV transistor (for example, the transistor TR13) included in the row decoder module 16. The conductive layer GC1 in the input/output region IOR1 is used as, for example, gate electrodes of the LV transistor and the VLV transistor included in the input/output module 11.

The contact C0 is provided on the conductive layer GC1. Two contacts CS1 belonging to a certain transistor are connected to two impurity diffusion regions (not illustrated) provided in the substrate 50. For example, the two impurity diffusion regions correspond to a source and a drain of the transistor, respectively. A shallow trench isolation (ST1) is appropriately provided on the substrate 50 according to the layout of the transistors.

The conductive layer 53 is provided on each of the contact CS1 and the contact C0. The conductive layer 53 is included in the wiring layer D0. The conductive layer 54 is provided above the conductive layer 53 through the contact C1. The conductive layer 54 is included in the wiring layer D2. The conductive layer 55 is provided above the conductive layer 54 through the contact C2. The conductive layer 55 is included in the wiring layer D2. The conductive layer 56 is provided above the conductive layer 55 through the contact C3. The conductive layer 69 arranged to face the conductive layer 56 is in contact with the conductive layer 56. The conductive layers 56 and 69 correspond to the joint pads BP used for joint between the circuit chip DC1 and the circuit chip DC2. The conductive layers 56 and 69 contain, for example, copper.

The contact C4 is provided on the conductive layer 69. The contact C4 penetrates the insulating layer 63 and the substrate 60. The contact C4 and the substrate 60 are insulated by an insulating film INS. The contact C4 corresponds to a through-via (TSV: through silicon via).

The conductive layer GC2 is provided on a gate insulating film provided on the substrate 60. The conductive layer GC2 in the sense region SRb2 is used, for example, as gate electrodes of the HV transistor and the LV transistor (for example, transistor T8) included in the sense amplifier module 17. The conductive layer GC2 in the transfer region XR2 is used, for example, as gate electrodes of the HV transistor and the LV transistor (for example, the transistor TR0) included in the row decoder module 16.

The contact C5 is provided on the conductive layer GC2. The two contacts CS2 belonging to a certain transistor are connected to two impurity diffusion regions (not illustrated) provided in the substrate 60. For example, the two impurity diffusion regions correspond to a source and a drain of the transistor, respectively. The ST1 is appropriately provided on the substrate 60 according to the layout of the transistor. The contacts C5 and CS2 are longer than the contacts C0 and CS1.

The conductive layer 65 is provided on each of the contact CS2, the contact C4, and the contact C5. The conductive layer 65 is included in the wiring layer MD0. The conductive layer 66 is provided above the conductive layer 65 through the contact C6. The conductive layer 66 is included in the wiring layer MD1. The conductive layer 66 may be provided in a current path between the contacts CS2 and C4, or may be provided in a current path between the contact CS2 and the contact C7. The conductive layer 67 is provided above the conductive layer 66 through the contact C7. The conductive layer 67 is included in the wiring layer MD2. The conductive layer 68 is provided above the conductive layer 67 through the contact C8. The conductive layer 26 arranged to face the conductive layer 68 is in contact with the conductive layer 68. The conductive layers 68 and 26 correspond to the joint pads BP used for joint between the memory chip DC0 and the circuit chip DC2. The conductive layers 68 and 26 contain, for example, copper.

As described above, in the first embodiment, the substrate 50, the circuit provided on the substrate 50, the substrate 60, and the circuit provided on the substrate 60 are arranged in this order in the 22 direction.

With the above configuration, the conductive layer 24a (bit line BL) in the memory region MRb is electrically connected to the HV transistor and the LV transistor provided in the sense region SRb2 and the LV transistor and the VLV transistor provided in the sense region SRb1. The conductive layer 24b in the hookup region HR is electrically connected to the HV transistor and the LV transistor provided in the transfer region XR2, and the LV transistor and the VLV transistor provided in the transfer region XR1. The conductive layer 24c in the input/output region IOR0 is electrically connected to the LV transistor and the VLV transistor provided in the input/output region IOR1.

### 1.3 Effects According to the First Embodiment

According to the first embodiment, the memory chip DC0 includes the memory cell array 10 including the word line WL and the bit line BL. The circuit chip DC2 includes the substrate 60 and a first circuit provided on the substrate 60, and is in contact with the memory chip DC0. The circuit chip DC1 includes the substrate 50 and a second circuit provided on the substrate 50, and is in contact with the circuit chip DC2. The memory chip DC0 and the circuit chip DC2 are arranged in this order in the Z1 direction from the word line WL to the bit line BL. The first circuit includes a transistor (for example, transistor T8) in the sense amplifier module 17, which is an HV transistor connected to the bit line BL, and a transistor (for example, the transistor TR0) in the row decoder module 16, which is an HV transistor connected to the word line WL. The second circuit includes a transistor in the input/output module 11, which is a VLV transistor connected to the input/output pad PAD. As a result, the transistors can be arranged in two chips in a dispersed manner. Therefore, an area of one chip can be reduced as compared with a case where the transistor is arranged in one chip. Therefore, a state in which the size of the circuit chip limits the size of the memory device can be avoided, and an increase in the area of the memory device can be suppressed.

In addition, a driver that drives the memory cell array 10 is disposed in the circuit chip DC2, so that the wiring length, the number of contacts, and the number of joint pads BP can be reduced as compared with a case where the driver is arranged in the circuit chip DC1. This makes possible to suppress deterioration of yield.

In addition, the HV transistor is arranged on the circuit chip DC2 and the VLV transistor is arranged on the circuit chip DC1, so that the HV transistor and the VLV transistor can be arranged on different chips. As a result, the length of the contact CS1 of the VLV transistor can be made shorter than that of the contact CS2 of the HV transistor as compared with a case where the HV transistor and the VLV transistor are arranged on the same chip. Therefore, the size of the VLV transistor can be made smaller than the size of the HV transistor.

### 1.4 Modification of First Embodiment

In the first embodiment described above, the case where the input/output pad PAD is provided in the memory chip DC0 has been described, but the present invention is not limited thereto. For example, the input/output pad PAD may be provided in the circuit chip DC1. Hereinafter, a configuration different from that of the first embodiment will be mainly described. Description of configurations comparable with those of the first embodiment will be omitted as appropriate.

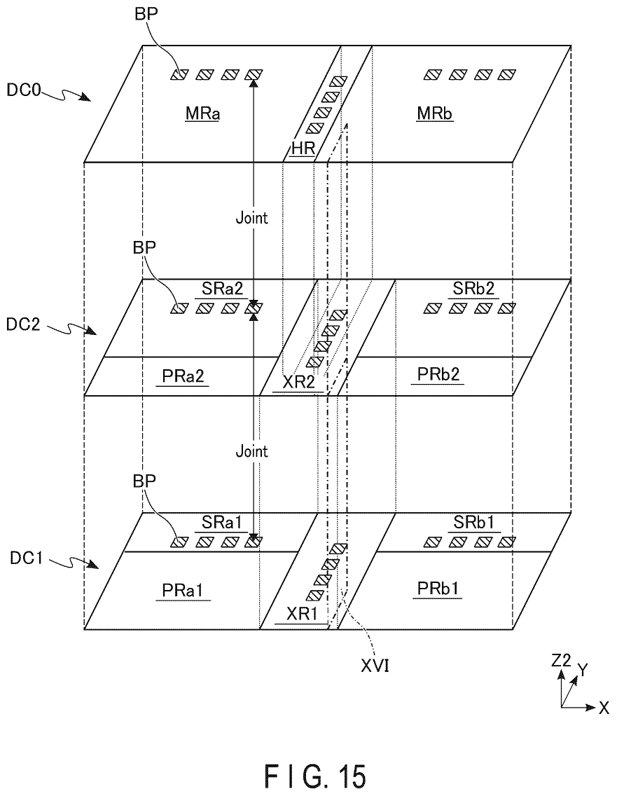

FIG. 15 is a perspective view illustrating an example of a bonded structure of a memory device and a planar layout of each chip according to a modification of the first embodiment. FIG. 15 corresponds to FIG. 12 in the first embodiment.

As illustrated in FIG. 15, each of the memory chip DC0 and the circuit chips DC1 and DC2 may not have an input/output region.

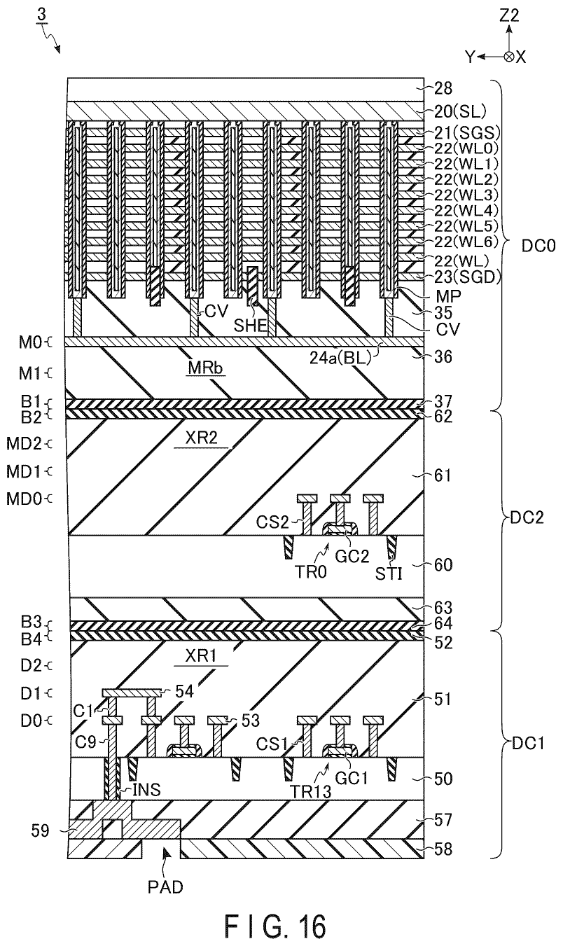

FIG. 16 is a cross-sectional view taken along a plane XVI of FIG. 15, illustrating an example of a cross-sectional structure of the memory device according to the modification of the first embodiment. The plane XVI is a plane including a memory region MRb of a memory chip DC0, a transfer region XR1 of a circuit chip DC1, and a transfer region XR2 of a circuit chip DC2. FIG. 16 corresponds to FIG. 14 in the first embodiment.

As illustrated in FIG. 16, the memory device 3 may include a surface passivation layer 58, an insulating layer 57, a conductive layer 59, and a contact C9 in the circuit chip DC1 in place of the surface passivation layer 30, the insulating layer 31, the conductive layer 27, and the contact CC0. In addition, the memory device 3 may further include a substrate 28 in the memory chip DC0.

The substrate 28 is, for example, a silicon substrate. The substrate 28 is provided on the semiconductor layer 20 on a side opposite to the memory cell array 10 with respect to the semiconductor layer 20, for example. The substrate 28 may be provided above the semiconductor layer 20 through an insulating layer (not illustrated).

The insulating layer 57 is provided on the substrate 50 on a side opposite to the circuit provided on the substrate 50 with respect to the substrate 50. The surface passivation layer 58 is provided on the insulating layer 57. The surface passivation layer 58 is a layer corresponding to a surface of the memory device 3, and includes, for example, a resin material such as polyimide. In the transfer region XR1 (or the peripheral circuit region PR1 (not illustrated)), a part of the surface passivation layer 58 is removed. The conductive layer 59 is exposed from a portion from which the surface passivation layer 58 is removed.

The conductive layer 59 is provided in the insulating layer 57. A portion of the conductive layer 59 exposed from a portion from which the surface passivation layer 58 is removed is used as the input/output pad PAD.

The contact C9 is provided on a surface of the conductive layer 59 on the substrate 50 side. The contact C9 penetrates the substrate 50. The contact C9 and the substrate 50 are insulated by the insulating film INS. The contact C9 corresponds to a through-via.

The contact C9 is connected to the LV transistor and the VLV transistor included in the input/output module 11 in the transfer region XR1 (or the peripheral circuit region PR1 (not illustrated)) through the conductive layers 53 and 54, the contacts C1 and CS1, and the like, for example.

With the above configuration, the LV transistor and the VLV transistor included in the input/output module 11 are connected to the input/output pad PAD without passing through the memory chip DC0 and the circuit chip DC2.

According to the modification of the first embodiment, the input/output pad PAD is disposed at a position overlapping the memory cell array 10 as viewed in the Z direction on the surface of the circuit chip DC1 opposite to the joint surface with the circuit chip DC2. As a result, the input/output regions IOR0, IOR1, and IOR2 can be reduced from the memory chip DC0 and the circuit chips DC1 and DC2, respectively. Therefore, the area of the memory device 3 can be reduced.

In the modification of the first embodiment, similarly to the first embodiment, the thickness of the substrate 60 is about 10 μm due to the inclusion of the HV transistor, whereas the substrate 50 does not include the HV transistor, so that the thickness can be about 1 μm. Therefore, the cost of forming the through-via in the substrate 50 can be reduced.

### 2. Second Embodiment

Next, a memory device according to a second embodiment will be described. In the second embodiment, circuit chips DC1 and DC2 join together such that a direction from a substrate 50 toward a circuit provided on the substrate 50 is a Z2 direction, whereas a direction from a substrate 60 toward a circuit provided on the substrate 60 is a Z1 direction. Hereinafter, a configuration different from that of the first embodiment will be mainly described. Description of configurations comparable with those of the first embodiment will be omitted as appropriate.

### 2.1 Structure of Memory Device

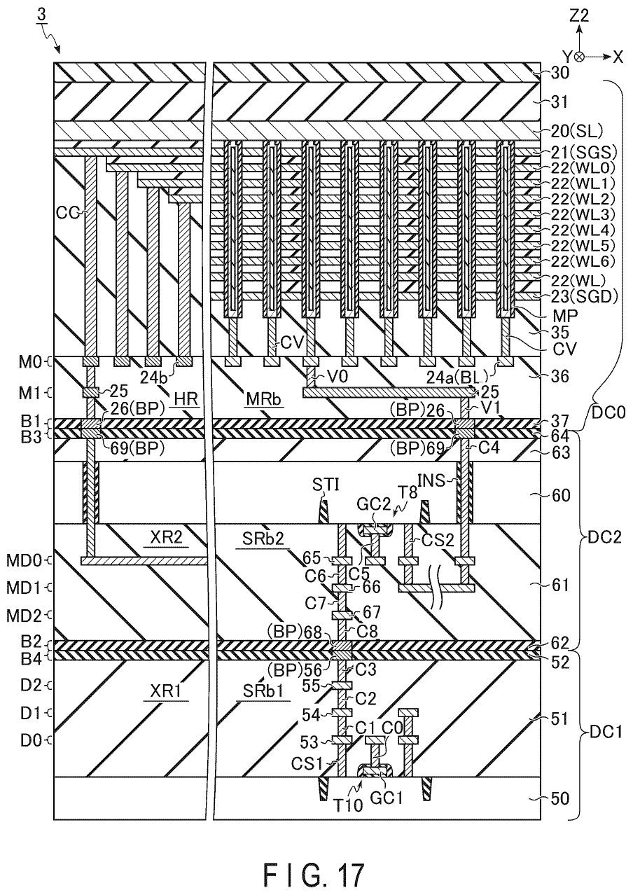

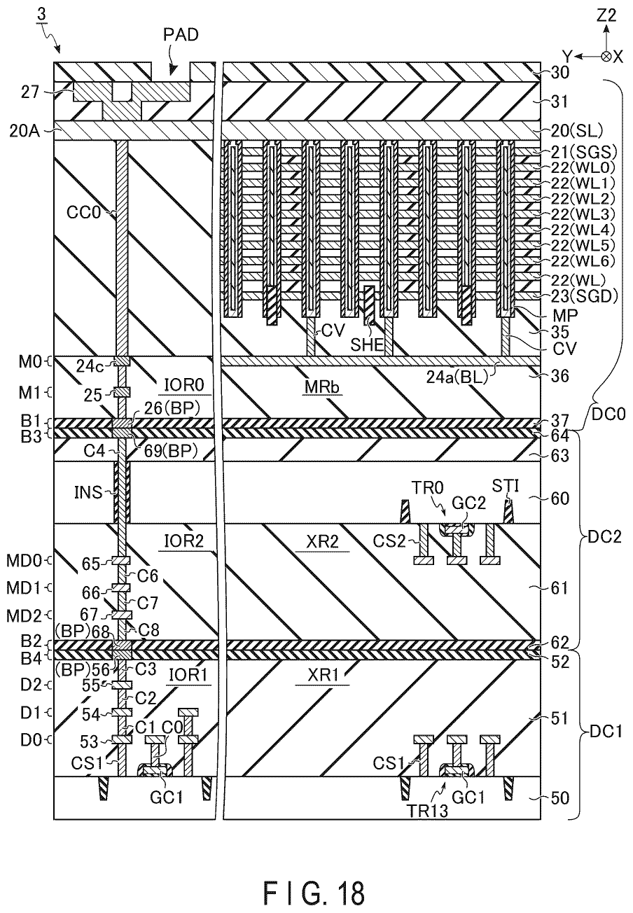

FIGS. 17 and 18 are cross-sectional views illustrating an example of a cross-sectional structure of the memory device according to the second embodiment. FIGS. 17 and 18 correspond to FIGS. 13 and 14 in the first embodiment, respectively.

As illustrated in FIGS. 17 and 18, in the second embodiment, the substrate 50, the circuit provided on the substrate 50, the circuit provided on the substrate 60, and the substrate 60 are arranged in this order in the Z2 direction.

Specifically, an insulating layer 52 is in contact with an insulating layer 62 included in the circuit chip DC2. A boundary between the insulating layer 52 and the insulating layer 62 corresponds to a joint surface between the circuit chip DC1 and the circuit chip DC2. Then, a conductive layer 68 in the insulating layer 62 arranged to face a conductive layer 56 in the insulating layer 52 is in contact with the conductive layer 56. That is, a joint layer B4 is in contact with a joint layer B2.

In addition, an insulating layer 64 is in contact with an insulating layer 37 included in a memory chip DC0. A boundary between the insulating layer 64 and the insulating layer 37 corresponds to a joint surface between the circuit chip DC2 and the memory chip DC0. Then, a conductive layer 26 in the insulating layer 37 arranged to face a conductive layer 69 in the insulating layer 64 is in contact with the conductive layer 69. That is, the joint layer B3 is in contact with the joint layer B1.

With the above configuration, a conductive layer 24a (bit line BL) in a memory region MRb is electrically connected to an HV transistor and an LV transistor provided in a sense region SRb2 or an LV transistor and a VLV transistor provided in a sense region SRb1. The conductive layer 24b in the hookup region HR is electrically connected to the HV transistor and the LV transistor provided in the transfer region XR2, and the LV transistor and the VLV transistor provided in the transfer region XR1. A conductive layer 24c in an input/output region IOR0 is electrically connected to the LV transistor and the VLV transistor provided in an input/output region IOR1.

### 2.2 Effects According to the Second Embodiment

According to the second embodiment, a first circuit provided on the substrate 60, the substrate 60, a second circuit provided on the substrate 50, and the substrate 50 are arranged in this order in the Z1 direction. As described above, even in a face-to-face structure in which the circuit chips DC1 and DC2 face each other, it is possible to achieve the comparable effect with that of the face-to-back structure in which the circuit chips DC1 and DC2 face the same direction as in the first embodiment.

### 2.3 Modification of Second Embodiment

In the second embodiment described above, the case where the input/output pad PAD is provided in the memory chip DC0 has been described, but the present invention is not limited thereto. For example, the input/output pad PAD may be provided in the circuit chip DC1. Hereinafter, a configuration different from that of the second embodiment will be mainly described. Description of configurations comparable with those of the second embodiment will be omitted as appropriate.

In a modification of the second embodiment, similarly to the modification of the first embodiment, each of the memory chip DC0 and the circuit chips DC1 and DC2 may not have an input/output region.

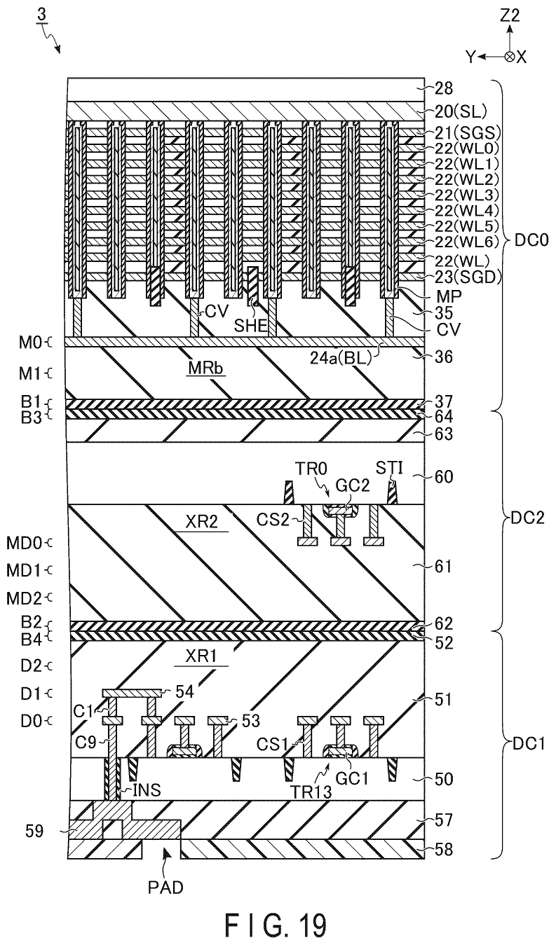

FIG. 19 is a cross-sectional view illustrating an example of a cross-sectional structure of a memory device according to the modification of the second embodiment. FIG. 19 corresponds to FIG. 16 in the modification of the first embodiment.

As illustrated in FIG. 19, a memory device 3 may include a surface passivation layer 58, an insulating layer 57, a conductive layer 27, and a contact C9 in a circuit chip DC1 in place of the surface passivation layer 30, the insulating layer 31, the conductive layer 27, and the contact CC0. In addition, the memory device 3 may further include a substrate 28 in the memory chip DC0.

The substrate 28 is, for example, a silicon substrate. The substrate 28 is provided on the semiconductor layer 20 on a side opposite to the memory cell array 10 with respect to the semiconductor layer 20, for example. The substrate 28 may be provided above the semiconductor layer 20 through an insulating layer (not illustrated).

The insulating layer 57 is provided on the substrate 50 on a side opposite to the circuit provided on the substrate 50 with respect to the substrate 50. The surface passivation layer 58 is provided on the insulating layer 57. The surface passivation layer 58 is a layer corresponding to a surface of the memory device 3, and includes, for example, a resin material such as polyimide. In the transfer region XR1 (or the peripheral circuit region PR1 (not illustrated)), a part of the surface passivation layer 58 is removed. The conductive layer 59 is exposed from a portion from which the surface passivation layer 58 is removed.

The conductive layer 59 is provided in the insulating layer 57. A portion of the conductive layer 59 exposed from a portion from which the surface passivation layer 58 is removed is used as the input/output pad PAD.

The contact C9 is provided on a surface of the conductive layer 59 on the substrate 50 side. The contact C9 penetrates the substrate 50. The contact C9 and the substrate 50 are insulated by the insulating film INS. The contact C9 corresponds to a through-via.

The contact C9 is connected to the LV transistor and the VLV transistor included in the input/output module 11 in the transfer region XR1 (or the peripheral circuit region PR1 (not illustrated)) through the conductive layers 53 and 54, the contacts C1 and CS1, and the like, for example.

With the above configuration, the LV transistor and the VLV transistor included in the input/output module 11 are connected to the input/output pad PAD without passing through the memory chip DC0 and the circuit chip DC2.

According to the modification of the second embodiment, the input/output pad PAD is disposed at a position overlapping the memory cell array 10 as viewed in the Z direction on the surface of the circuit chip DC1 opposite to the joint surface with the circuit chip DC2. As a result, the input/output regions IOR0, IOR1, and IOR2 can be reduced from the memory chip DC0 and the circuit chips DC1 and DC2, respectively. Therefore, the area of the memory device 3 can be reduced.

Further, since the substrate 50 does not include the HV transistor, the thickness can be set to about 1 μm. Therefore, the cost of forming the through-via in the substrate 50 can be reduced.

### 3. Third Embodiment

Next, a memory device according to a third embodiment will be described. In the third embodiment, a circuit chip DC1 is joined to a memory chip MC on a side opposite to a circuit chip DC2 with respect to a memory chip MC. Hereinafter, a configuration different from that of the first embodiment will be mainly described. Description of configurations comparable with those of the first embodiment will be omitted.

### 3.1 Structure of Memory Device

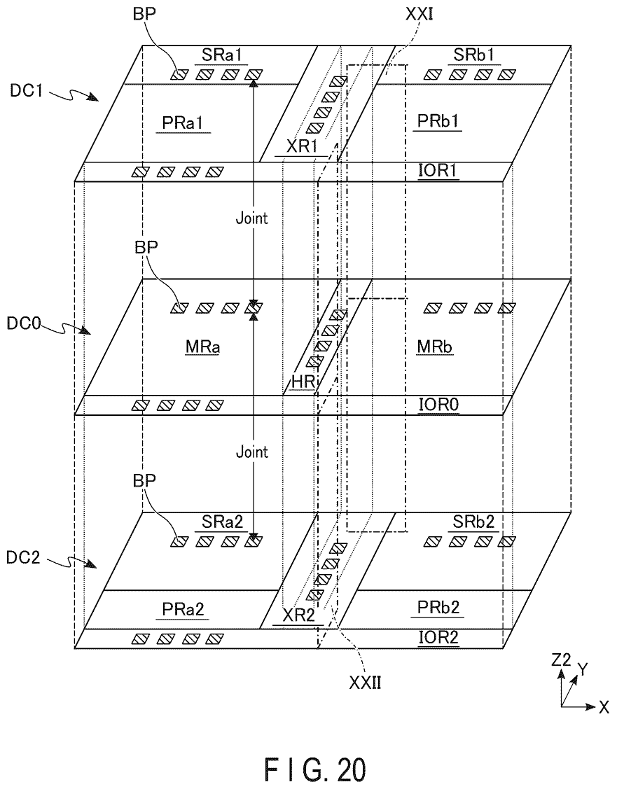

FIG. 20 is a perspective view illustrating an example of a bonded structure of the memory device and a planar layout of each chip according to the third embodiment. FIG. 20 corresponds to FIG. 12 in the first embodiment.

As illustrated in FIG. 20, a memory device 3 has, for example, a structure in which a circuit chip DC2, a memory chip DC0, and a circuit chip DC1 are stacked in order from the bottom. The circuit chip DC2 and the memory chip DC0, and the memory chip DC0 and the circuit chip DC1 are bonded by a plurality of joint pads BP. The individual planar layouts of the memory chip DC0 and the circuit chips DC1 and DC2 are comparable with those of the first embodiment.

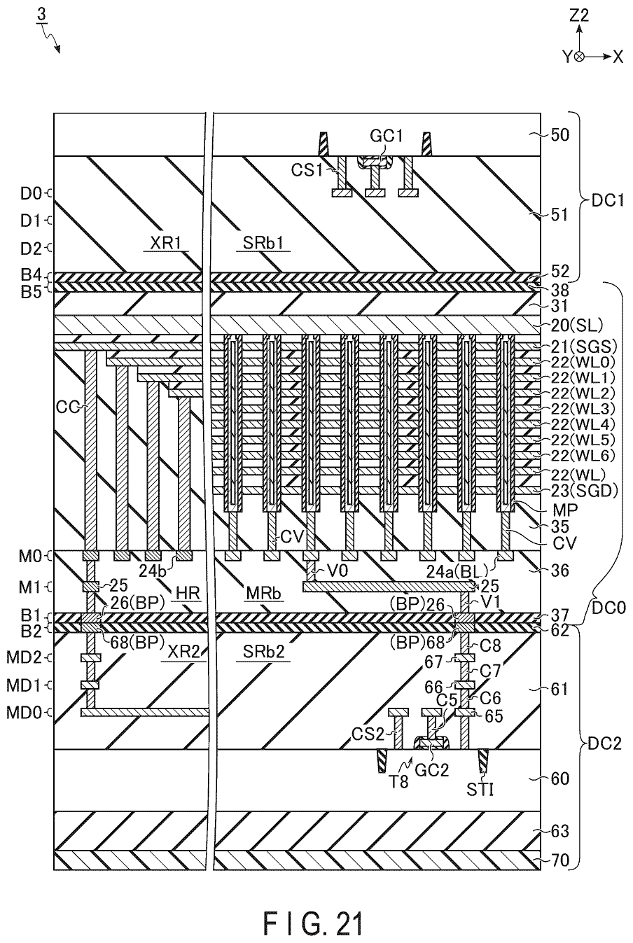

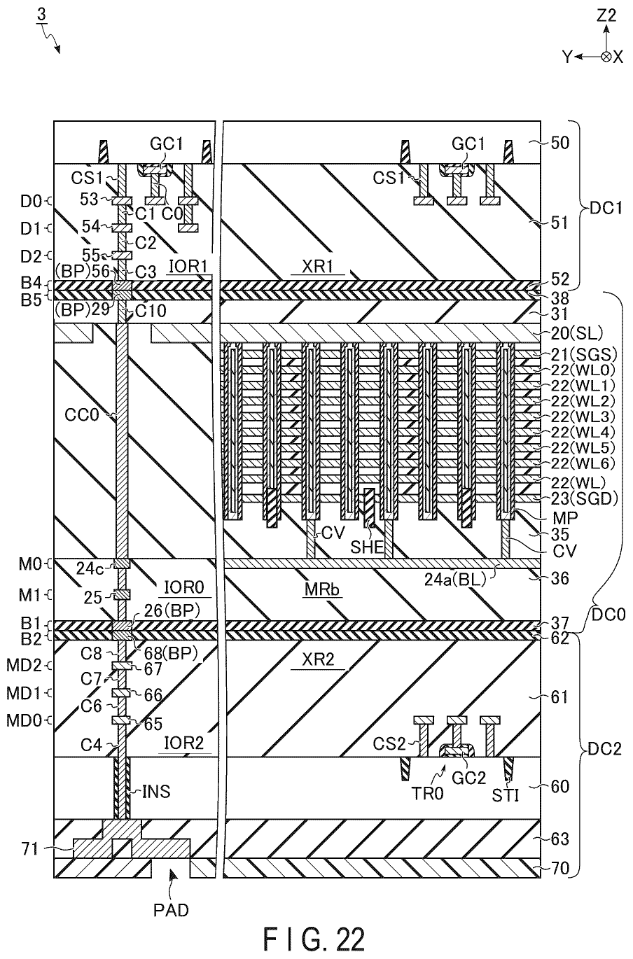

FIG. 21 is a cross-sectional view taken along a plane XXI of FIG. 20, illustrating an example of a cross-sectional structure of the memory device according to the third embodiment. FIG. 22 is a cross-sectional view taken along a plane XXII of FIG. 20, illustrating an example of a cross-sectional structure of the memory device according to the third embodiment. The plane XXI is a plane including a memory region MRb and a hookup region HR of the memory chip DC0, a sense region SRb1 and a transfer region XR1 of the circuit chip DC1, and a sense region SRb2 and a transfer region XR2 of the circuit chip DC2. The plane XXII is a plane including the memory region MRb and an input/output region IOR0 of the memory chip DC0, the transfer region XR1 and an input/output region IOR1 of the circuit chip DC1, and the transfer region XR2 and an input/output region IOR2 of the circuit chip DC2. FIGS. 20 and 21 correspond to FIGS. 13 and 14 in the first embodiment, respectively.

As illustrated in FIGS. 21 and 22, the memory device 3 includes an insulating layer 38, a conductive layer 29, and a contact C10 in place of the surface passivation layer 30, the semiconductor layer 20A, and the conductive layer 27 in the memory chip DC0. The memory device 3 has the configuration comparable with that of the first embodiment in the circuit chip DC1. The memory device 3 includes a surface passivation layer 70 and a conductive layer 71 instead of the insulating layer 64 and the conductive layer 69 in the circuit chip DC2.

In the input/output region IOR2, the conductive layer 71 is provided in the insulating layer 63. A part of the conductive layer 71 is exposed on a surface of the memory device 3 and is used as an input/output pad PAD.

The surface passivation layer 70 is provided on the insulating layer 63. The surface passivation layer 70 is a layer corresponding to the surface of the memory device 3, and includes, for example, a resin material such as polyimide. In the input/output region IOR2, a part of the surface passivation layer 30 is removed. The conductive layer 71 is exposed from a portion from which the surface passivation layer 30 is removed.

A contact C4 is provided on a surface of the conductive layer 71 on the substrate 60 side. The contact C4 is connected to a conductive layer 26 included in the memory chip DC0 through conductive layers 65 to 68, contacts C6 to C8, and the like.

In the input/output region IOR0, the conductive layer 26 is connected to the contact CC0 through conductive layers 24c and 25 and contacts V0 and V1. The contact CC0 penetrates the semiconductor layer 20. The contact CC0 and the semiconductor layer 20 are insulated from each other by an insulating film.

A contact C10 is provided on the contact CC0. The contact C10 penetrates an insulating layer 31. A conductive layer 29 is provided on the contact C10.

On the insulating layer 31, the insulating layer 38 is provided so as to include the conductive layer 29 in the same layer. The insulating layer 38 is in contact with an insulating layer 52 included in the circuit chip DC1. A boundary between the insulating layer 38 and the insulating layer 52 corresponds to a joint surface between the memory chip DC0 and the circuit chip DC1. The insulating layer 38 is, for example, a silicon oxide film. Hereinafter, a layer having a height at which the conductive layer 29 and the insulating layer 38 are provided is referred to as a joint layer B5.

The conductive layer 29 is provided in the insulating layer 38. The conductive layer 56 arranged to face the conductive layer 29 is in contact with the conductive layer 29. The conductive layers 29 and 56 correspond to the joint pads BP used for joint between the memory chip DC0 and the circuit chip DC1. The conductive layers 29 and 56 contain, for example, copper.

In the input/output region IOR1, the conductive layer 56 is connected to a transistor provided on the substrate 50 through the contacts CS1 and C1 to C3, the conductive layer 53 to 55, and the like.

With the above configuration, the input/output pad PAD provided on the circuit chip DC2 is connected to a transistor provided on the circuit chip DC1 through the memory chip DC0.

Similarly to the first embodiment, in the circuit chip DC2, an HV transistor and an LV transistor included in the sense amplifier module 17 are provided in the sense region SRb2. An HV transistor and an LV transistor included in the row decoder module 16 are provided in the transfer region XR2. Furthermore, in the circuit chip DC1, an LV transistor and a VLV transistor included in the sense amplifier module 17 can be provided in the sense region SRb1. The transfer region XR1 can be provided with an LV transistor and a VLV transistor included in the row decoder module 16.

### 3.2 Effects According to the Third Embodiment

According to the third embodiment, the circuit chip DC1 is in contact with the memory chip DC0. The circuit chip DC1, the memory chip DC0, and the circuit chip DC2 are arranged in this order in the Z1 direction. As described above, even in the structure in which the circuit chips DC1 and DC2 sandwich the memory chip DC0, it is possible to achieve the comparable effect with that of the structure in which the circuit chips DC1 and DC2 stacked on the memory chip DC0 are joined as in the first embodiment and the second embodiment.

### 3.3 Modification of Third Embodiment

In the third embodiment described above, the case where the input/output pad PAD is provided on the circuit chip DC2 has been described, but the present invention is not limited thereto. For example, the input/output pad PAD may be provided in the circuit chip DC1. Hereinafter, a configuration different from that of the third embodiment will be mainly described. Description of configurations comparable with those of the third embodiment will be omitted as appropriate.

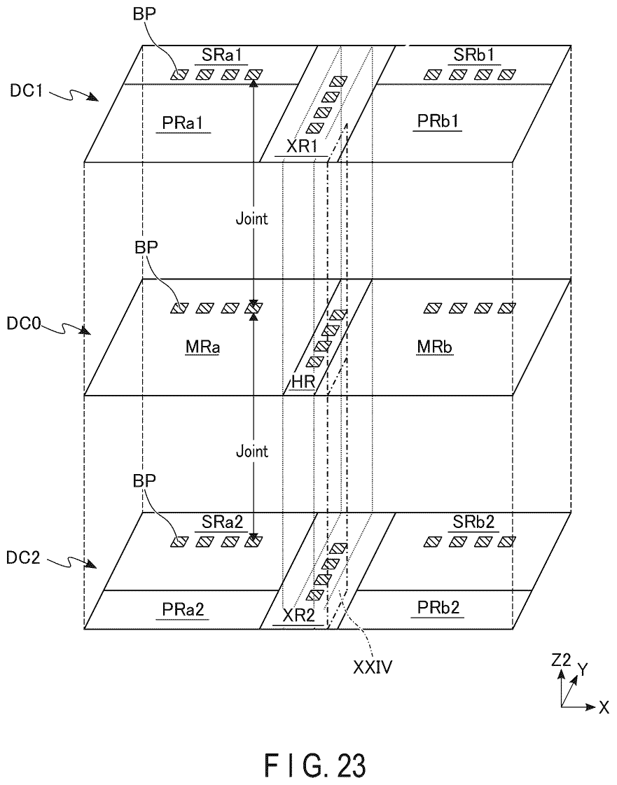

FIG. 23 is a perspective view illustrating an example of a bonded structure of a memory device and a planar layout of each chip according to a modification of the third embodiment. FIG. 23 corresponds to FIG. 20 in the third embodiment.

As illustrated in FIG. 23, each of a memory chip DC0 and circuit chips DC1 and DC2 may not have an input/output region.

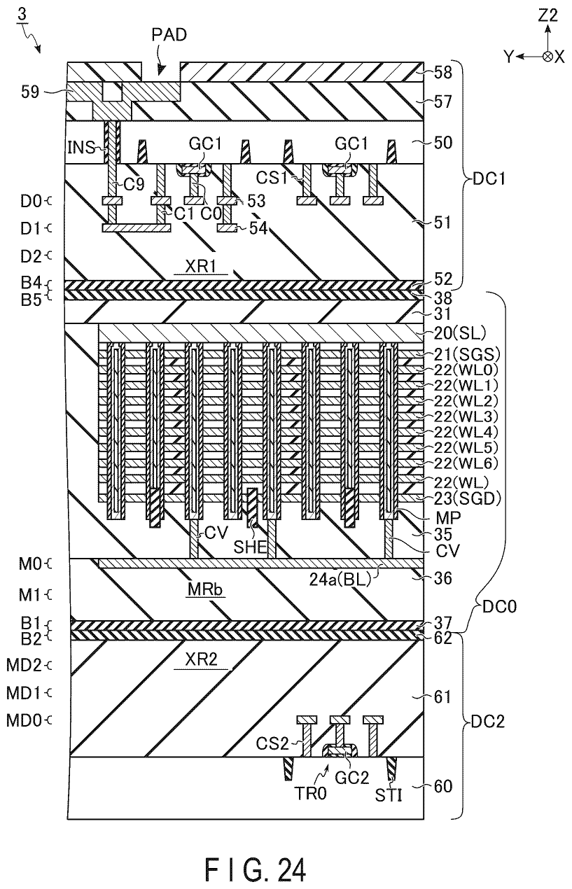

FIG. 24 is a cross-sectional view taken along a plane XXIV of FIG. 23, illustrating an example of a cross-sectional structure of a memory device according to the modification of the third embodiment. The plane XXIV is a plane including a memory region MRb of the memory chip DC0, a transfer region XR1 of the circuit chip DC1, and a transfer region XR2 of the circuit chip DC2. FIG. 24 corresponds to FIG. 22 in the third embodiment.

As illustrated in FIG. 24, the memory device 3 may include a surface passivation layer 58, an insulating layer 57, a conductive layer 59, and a contact C9 in the circuit chip DC1 in place of the surface passivation layer 70, the insulating layer 63, the conductive layer 71, and the contacts CC0, C4, and C10.

The insulating layer 57 is provided on the substrate 50 on a side opposite to the circuit provided on the substrate 50 with respect to the substrate 50. The surface passivation layer 58 is provided on the insulating layer 57. The surface passivation layer 58 is a layer corresponding to a surface of the memory device 3, and includes, for example, a resin material such as polyimide. In the transfer region XR1 (or the peripheral circuit region PR1 (not illustrated)), a part of the surface passivation layer 58 is removed. The conductive layer 59 is exposed from a portion from which the surface passivation layer 58 is removed.

The conductive layer 59 is provided in the insulating layer 57. A portion of the conductive layer 59 exposed from a portion from which the surface passivation layer 58 is removed is used as the input/output pad PAD.

The contact C9 is provided on a surface of the conductive layer 59 on the substrate 50 side. The contact C9 penetrates the substrate 50. The contact C9 and the substrate 50 are insulated by the insulating film INS. The contact C9 corresponds to a through-via.

The contact C9 is connected to the LV transistor and the VLV transistor included in the input/output module 11 in the transfer region XR1 (or the peripheral circuit region PR1 (not illustrated)) through the conductive layers 53 and 54, the contacts C1 and CS1, and the like, for example.

With the above configuration, the LV transistor and the VLV transistor included in the input/output module 11 are connected to the input/output pad PAD without passing through the memory chip DC0 and the circuit chip DC2.

According to the modification of the third embodiment, the input/output pad PAD is disposed at a position overlapping the memory cell array 10 as viewed in the Z direction on the surface of the circuit chip DC1 opposite to the joint surface with the circuit chip DC2. As a result, the input/output regions IOR0 to IOR2 can be reduced from the memory chip DC0 and the circuit chips DC1 and DC2, respectively. Therefore, the area of the memory device 3 can be reduced.

Further, since the substrate 50 does not include

the HV transistor, the thickness can be set to about 1 μm. Therefore, the cost of forming the through-via in the substrate 50 can be reduced.

### 4. Fourth Embodiment

Next, a memory device according to a fourth embodiment will be described. In the fourth embodiment, an HV transistor and an LV transistor are provided in a circuit chip DC1, and an N-type HV transistor, a LV transistor, and a VLV transistor are provided in a circuit chip DC2. In the fourth embodiment, an HV transistor and an LV transistor may be provided in a circuit chip DC1, and an LV transistor and a VLV transistor may be provided in a circuit chip DC2. Hereinafter, a configuration different from that of the first embodiment will be mainly described. Description of configurations comparable with those of the first embodiment will be omitted as appropriate.

### 4.1 Structure of Memory Device

### Bonded Structure and Planar Layout

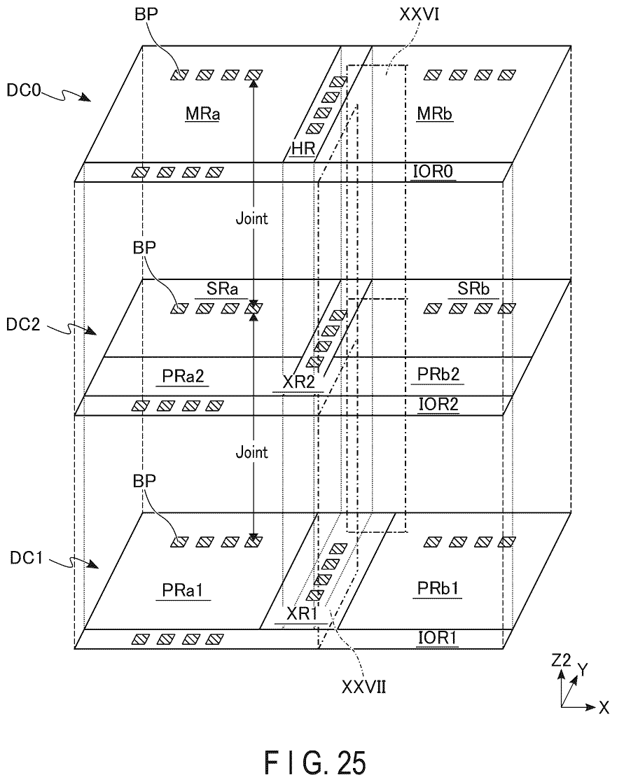

FIG. 25 is a perspective view illustrating an example of a bonded structure of the memory device and a planar layout of each chip according to the fourth embodiment. FIG. 25 corresponds to FIG. 12 in the first embodiment.

As illustrated in FIG. 25, a memory device 3 has, for example, a structure in which the circuit chip DC1, the circuit chip DC2, and a memory chip DC0 are stacked in this order from the bottom. The circuit chip DC1 and the circuit chip DC2, and the circuit chip DC2 and the memory chip DC0 are bonded by a plurality of joint pads BP.

The circuit chips DC1 and DC2 include CMOS circuits. In the circuit chip DC1, the HV transistor and the LV transistor are mainly formed. In the circuit chip DC2, the N-type HV transistor, the LV transistor, and the VLV transistor are mainly formed. In the memory chip DC0, a memory cell transistor MT is formed.

The planar layout of the memory chip DC0 is comparable with that of the first embodiment.

The circuit chip DC1 is divided into, for example, a transfer region XR1, peripheral circuit regions PRa1 and PRb1, and an input/output region IOR1 as viewed in the Z direction.

The transfer region XR1 is a region where the HV transistor and the LV transistor configuring the row decoder module 16 are arranged. In the transfer region XR1, all the transistors configuring the row decoder module 16 may be arranged. The transfer region XR1 is arranged so as to overlap the entire hookup region HR, a portion of the memory region MRa adjacent to the hookup region HR, and a portion of the memory region MRb adjacent to the hookup region HR as viewed in the Z direction. That is, a length of the transfer region XR1 in the X direction is longer than a length of the hookup region HR in the X direction. Note that a portion of the transfer region XR1 overlapping the hookup region HR does not overlap sense regions SRa2 and SRb2 of the circuit chip DC2 described later.

The peripheral circuit regions PRa1 and PRb1 are regions in which the HV transistors and the LV transistors configuring a register 12, a sequencer 13, a voltage generator 14, and a driver module 15 are arranged. The peripheral circuit regions PRa1 and PRb1 sandwich the transfer region XR1 in the X direction. The peripheral circuit regions PRa1 and PRb1 are arranged so as to overlap the memory regions MRa and MRb, respectively, as viewed in the Z direction.

The input/output region IOR1 is a region where a circuit, wiring, and the like for supplying a power supply voltage and the like to the circuit chip DC1 are formed. The input/output region IOR1 is aligned in the Y direction with the peripheral circuit regions PRa1 and PRb1 and the transfer region XR1. The input/output region IOR1 is arranged so as to overlap the input/output region IOR0 as viewed in the Z direction.

For example, as viewed in the Z direction, the circuit chip DC2 is divided into a transfer region XR2, sense regions SRa2 and SRb2, peripheral circuit regions PRa2 and PRb2, and an input/output region IOR2.

In the transfer region XR2, the transistors configuring the row decoder module 16 are hardly arranged. In the transfer region XR2, a part of the LV transistor and the VLV transistor configuring the row decoder module 16 may be arranged. The transfer region XR2 is arranged so as to overlap a hookup region HR but not to overlap the memory regions MRa and MRb as viewed in the Z direction. That is, the length of the transfer region XR2 in the X direction is comparable with the length of the hookup region HR in the X direction, and is shorter than the length of the transfer region XR1 in the X direction.

The sense regions SRa2 and SRb2 are regions in which an N-type HV transistor, an LV transistor, and a VLV transistor configuring the sense amplifier module 17 are arranged. In the sense region SR1, all the transistors configuring the sense amplifier module 17 may be arranged. The sense regions SRa2 and SRb2 sandwich the transfer region XR2 in the X direction. The sense regions SRa2 and SRb2 are arranged so as to overlap the memory regions MRa and MRb, respectively, as viewed in the Z direction. In addition, portions of the sense regions SRa2 and SRb2 adjacent to the transfer region XR2 are arranged so as to overlap the transfer region XR1 as viewed in the Z direction.

The peripheral circuit regions PRa2 and PRb2 are regions in which the LV transistors and the VLV transistors configuring the register 12, the sequencer 13, the voltage generator 14, and the driver module 15 are arranged. The peripheral circuit regions PRa2 and PRb2 sandwich the transfer region XR2 in the X direction. The peripheral circuit regions PRa2 and PRb2 are aligned in the Y direction with the sense regions SRa2 and SRb2, respectively. The peripheral circuit regions PRa2 and PRb2 are arranged so as to overlap the memory regions MRa and MRb, respectively, as viewed in the Z direction.

The input/output region IOR2 is a region where a circuit, wiring, and the like for supplying a power supply voltage and the like to the circuit chip DC2 are formed. The input/output region IOR2 is aligned in the Y direction with the peripheral circuit regions PRa2 and PRb2 and the transfer region XR2. The input/output region IOR2 is arranged so as to overlap the input/output regions IOR0 and IOR1 as viewed in the Z direction.

### Cross-Sectional Structure

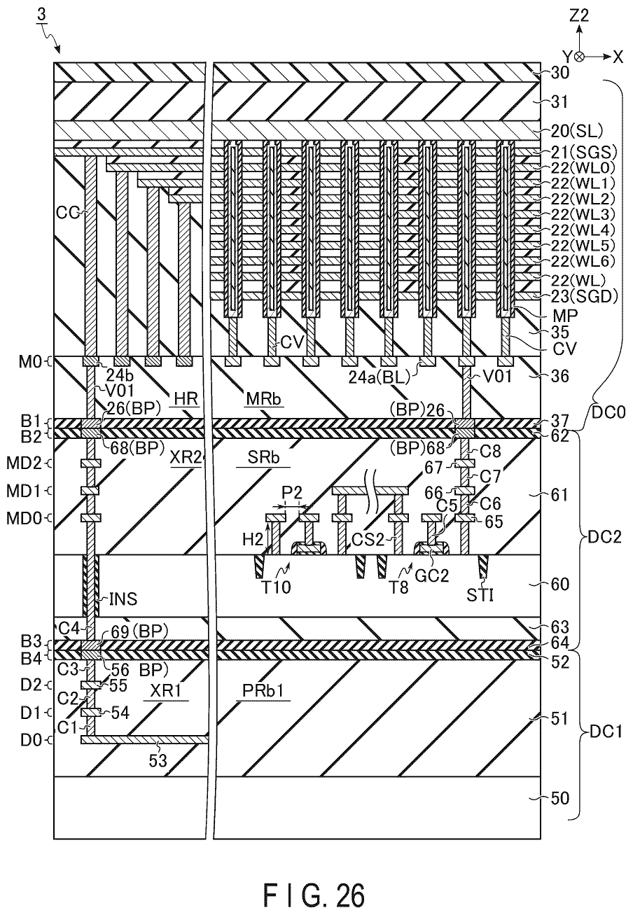

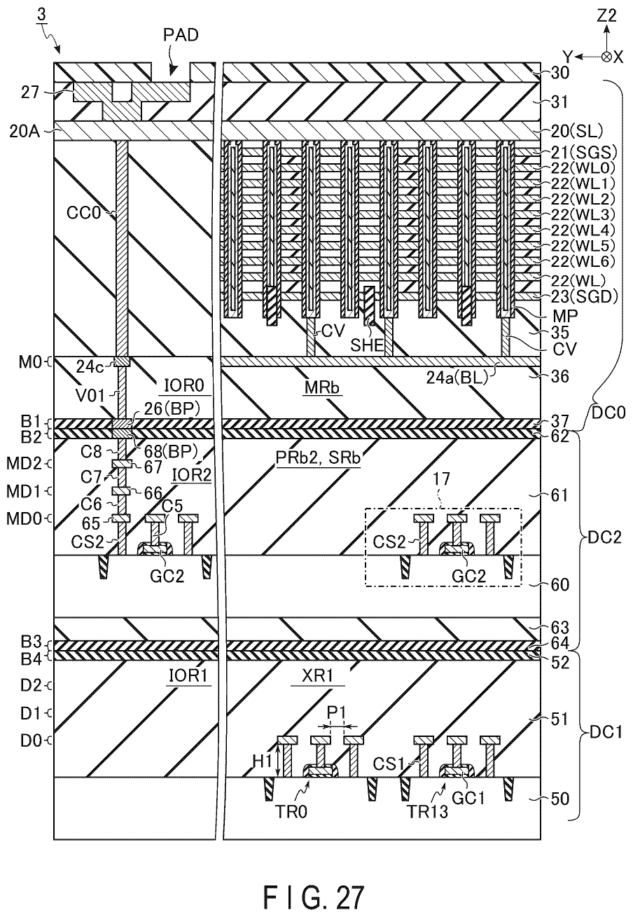

FIG. 26 is a cross-sectional view taken along a plane XXVI of FIG. 25, illustrating an example of a cross-sectional structure of the memory device according to the fourth embodiment. FIG. 27 is a cross-sectional view taken along a plane XXVII of FIG. 25, illustrating an example of a cross-sectional structure of the memory device according to the fourth embodiment. The plane XXVI is a plane including the memory region MRb and the hookup region HR of the memory chip DC0, the peripheral circuit region PRb1 and the transfer region XR1 of the circuit chip DC1, and the sense region SRb2 and the transfer region XR2 of the circuit chip DC2. The plane XXVII is a plane including the memory region MRb and the input/output region IOR0 of the memory chip DC0, the transfer region XR1 and the input/output region IOR1 of the circuit chip DC1, and the sense region SRb2, the peripheral circuit region PRb2, and the input/output region IOR2 of the circuit chip DC2.

As illustrated in FIGS. 26 and 27, the memory device 3 includes a contact V01 instead of the conductive layer 25 and the contacts V0 and V1 in the memory chip DC0.

The contact V01 is provided on each of a conductive layer 24a, a conductive layer 24b, and a conductive layer 24c. A conductive layer 26 is provided on the contact V01. Therefore, the conductive layer 26 is disposed so as to overlap the corresponding conductive layer 24a as viewed in the Z direction.

The circuit chip DC1 is provided with an HV transistor and an LV transistor. Therefore, a conductive layer GC1 in the transfer region XR1 is used, for example, as gates electrode of an HV transistor and an LV transistor (for example, transistors TR0 and TR13) included in the row decoder module 16. A plurality of wirings (for example, the conductive layers 53 and 54 in the transfer region XR1) used for the HV transistor and the LV transistor included in the row decoder module 16 is arranged in the Y direction in the circuit chip DC1. Although not illustrated, the HV transistor provided in the circuit chip DC1 may have a triple well structure. The triple well structure is a structure in which a well region covering an impurity diffusion region in the substrate 50 is triplexed.

The circuit chip DC2 is provided with an N-type HV transistor, an LV transistor, and a VLV transistor. Therefore, the conductive layer GC2 in the sense region SRb is used, for example, as gate electrodes of an N-type HV transistor, an LV transistor, and a VLV transistor (for example, transistors T8 and T10) included in the sense amplifier module 17. A plurality of wirings (for example, the conductive layers 65 and 66 in the sense region SRb) used for the N-type HV transistor, the LV transistor, and the VLV transistor included in the sense amplifier module 17 is arranged in the X direction in the circuit chip DC2. In addition, the conductive layer GC2 in the input/output region IOR2 is used as, for example, gate electrodes of an LV transistor and a VLV transistor included in the input/output module 11.

A height H2 of the contact CS2 in the sense region SRb is lower than a height H1 of the contact CS1 in the transfer region XR1. A diameter of the contact CS2 in the sense region SRb is smaller than a diameter of the contact CS1 in the transfer region XR1. A size of the transistor in the sense region SRb is smaller than a size of the transistor in the transfer region XR1.

In addition, a pitch P1 in the Y direction between the conductive layers 53 or 54 in the wiring layer D0 of the transfer region XR1 is the minimum pitch in the circuit chip DC1. A pitch P2 in the X direction between the conductive layers 65 or 66 in the wiring layer MD0 of the sense region SRb is a minimum pitch in the circuit chip DC2. Here, the pitches Pl and P2 are designed independently of each other. The pitches Pl and P2 may be equal or different.

The HV transistor and the LV transistor of the transfer region XR1 in the circuit chip DC1, the N-type HV transistor, the LV transistor, and the VLV transistor in the sense region SRb in the circuit chip DC2, and the memory cell transistor MT in the memory region MRb in the memory chip DC0 can be provided at overlapping positions as viewed in the Z direction.

Note that the N-type HV transistor in the circuit chip DC2 may be replaced by the LV transistor. In this case, the memory device according to the fourth embodiment may have a configuration that an HV transistor and an LV transistor are provided in the circuit chip DC1 and an LV transistor and a VLV transistor are provided in the circuit chip DC2.

### Wiring Structure

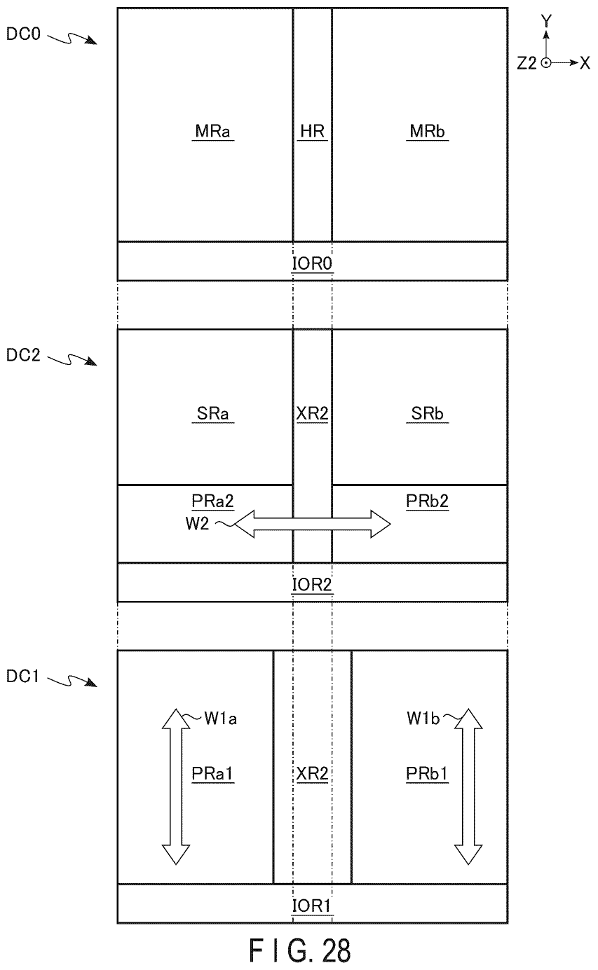

FIG. 28 is a schematic diagram illustrating an example of a wiring structure of the memory device according to the fourth embodiment. FIG. 28 illustrates a planar layout of the memory chip DC0 and the circuit chips DC1 and DC2 illustrated in FIG. 25, and representative wirings W1 and W2 provided in the circuit chips DC1 and DC2, respectively.

As illustrated in FIG. 28, wirings W1a and W1b are provided in the peripheral circuit regions PRa1 and PRb1 of the circuit chip DC1, respectively. In the peripheral circuit regions PRa2 and PRb2 of the circuit chip DC2, a wiring W2 is provided so as to cross the transfer region XR2 in the X direction.

The wirings W1a and W1b include, for example, wirings for reference voltage supply and power supply wirings for high voltage supply to be applied to the HV transistor like the wiring CG. As a result, a distance from the bit line BL and the source line SL can be increased as compared with a case where these power supply wirings are arranged in the circuit chip DC2. Therefore, the fluctuation of the power supply voltage due to the influence of coupling between the bit line BL and the source line SL can be suppressed.

In addition, the wirings W1a and W1b include, for example, global wirings extending in the Y direction. The global wiring includes, for example, wirings for transmitting signals for various circuits in the memory device 3 to cooperate with each other. As described above, the sense region SR is not provided in the circuit chip DC1. As a result, in the circuit chip DC1, there are few circuits that cross the memory device 3 in the X direction as viewed in the Z direction. Therefore, in the peripheral circuit regions PRa1 and PRb1 of the circuit chip DC1, regions for providing the wirings W1a and W1b extending in the Y direction among the global wirings can be relatively easily secured.

In addition, the wiring W2 includes, for example, a global wiring extending in the X direction. As described above, the transistors included in the row decoder module 16 are hardly provided in the transfer region XR2 of the circuit chip DC2. As a result, in the circuit chip DC2, there are few circuits that cross the memory device 3 in the Y direction as viewed in the Z direction. Therefore, in the peripheral circuit regions PRa2 and PRb2 of the circuit chip DC2 and the transfer region XR2, it is possible to relatively easily secure a region for providing the wiring W2 extending in the X direction among the global wirings. 4.2 Effects according to the fourth embodiment

According to the fourth embodiment, the first circuit provided on the substrate 60 includes the sense amplifier module 17 connected to the plurality of bit lines BL. The second circuit provided on the substrate 50 includes the row decoder module 16 connected to the plurality of word lines WL. The row decoder module 16 has a first portion overlapping the memory region MR of the sense amplifier module 17 and the memory cell array 10 as viewed in the Z direction. As a result, a width of the sense amplifier module 17 in the X direction can be made as long as the memory region MR as compared with a case where the row decoder module 16 and the sense amplifier module 17 are arranged in one chip. Therefore, the joint pad between the memory chip DC0 and the circuit chip DC2 and the corresponding bit line BL can be linearly connected in the Z direction without being shifted in the X direction. Therefore, the arrangement cost and the wiring length of the wiring can be reduced.

In addition, as described above, the row decoder module 16 and the sense amplifier module 17 are arranged on different circuit chips DC1 and DC2, respectively. In the wiring of the row decoder module 16, the first circuit includes a plurality of conductive layers 65 or 66 arranged in the X direction in the wiring layer MD0 closest to the substrate 60 or the wiring layer MD1 next closest thereto and each extending in the Y direction. The second circuit includes a plurality of conductive layers 53 or 54 arranged in the Y direction in the wiring layer D0 closest to the substrate 50 or the wiring layer DI next closest thereto and each extending in the X direction. The pitch P2 of the plurality of conductive layers 65 or 66 is the smallest in the circuit chip DC2. The pitch Pl of the plurality of conductive layers 53 or 54 is the smallest in the circuit chip DC1 and is independent of the pitch P2. As a result, it is possible to apply an optimum pitch as compared with a case where it is difficult to simultaneously minimize the pitches P1 and P2 as in a case where the row decoder module 16 and the sense amplifier module 17 are arranged in one circuit chip.

### 5. Fifth Embodiment

Next, a memory device according to a fifth embodiment will be described. In the fifth embodiment, circuit chips DC1 and DC2 are joined such that a direction from a substrate 50 toward a circuit provided on the substrate 50 is a Z2 direction, whereas a direction from a substrate 60 toward a circuit provided on the substrate 60 is a Z1 direction. Hereinafter, a configuration different from that of the fourth embodiment will be mainly described. Description of configurations comparable with those of the fourth embodiment will be omitted as appropriate.

### 5.1 Structure of Memory Device

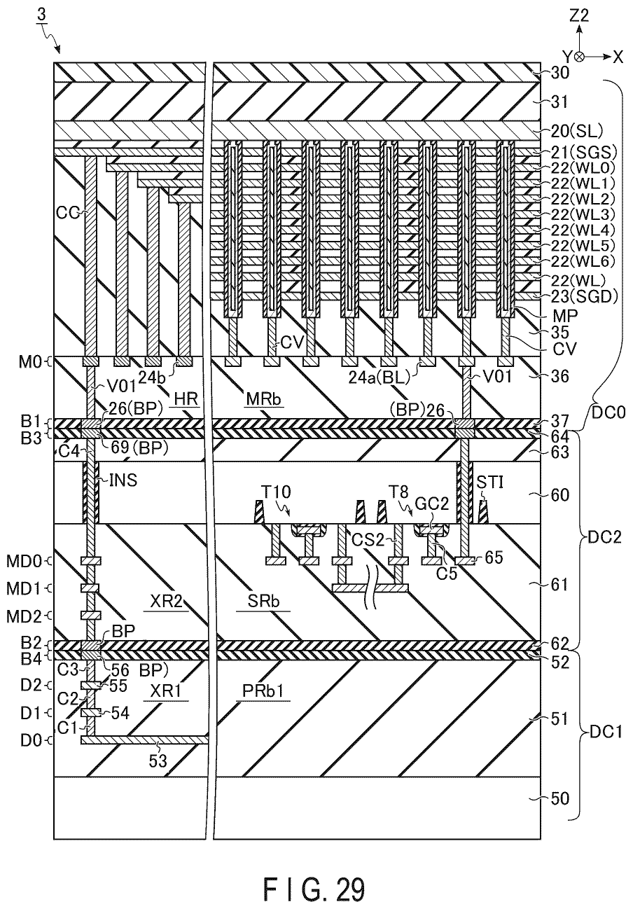

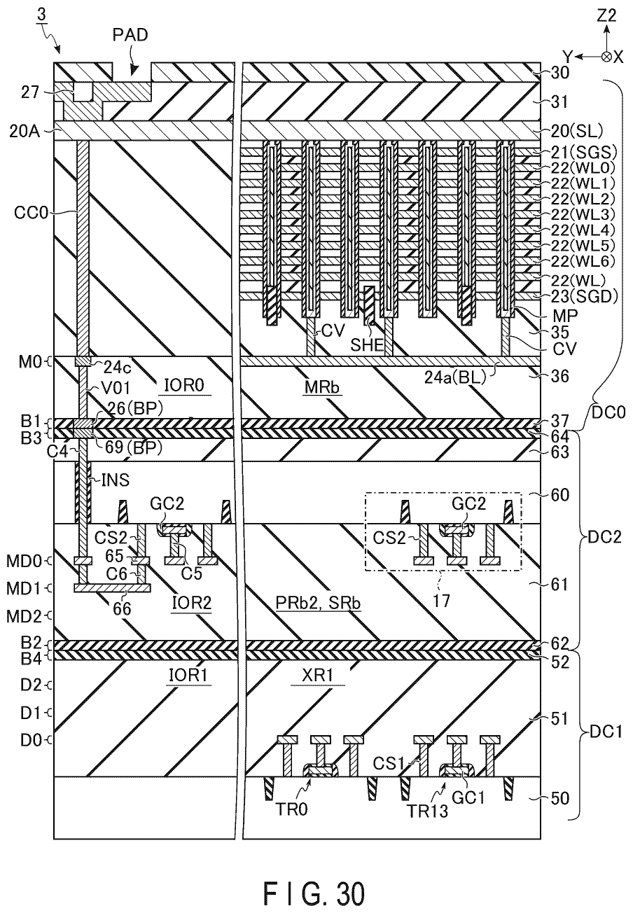

FIGS. 29 and 30 are cross-sectional views illustrating an example of a cross-sectional structure of the memory device according to the fifth embodiment. FIGS. 29 and 30 correspond to FIGS. 26 and 27 in the fourth embodiment, respectively.

As illustrated in FIGS. 29 and 30, in the fifth embodiment, the substrate 50, the circuit provided on the substrate 50, the circuit provided on the substrate 60, and the substrate 60 are arranged in this order in the Z2 direction.

Specifically, an insulating layer 52 is in contact with an insulating layer 62 included in the circuit chip DC2. A boundary between the insulating layer 52 and the insulating layer 62 corresponds to a joint surface between the circuit chip DC1 and the circuit chip DC2. Then, a conductive layer 68 in the insulating layer 62 arranged to face a conductive layer 56 in the insulating layer 52 is in contact with the conductive layer 56. That is, a joint layer B4 is in contact with a joint layer B2.

In addition, an insulating layer 64 is in contact with an insulating layer 37 included in a memory chip DC0. A boundary between the insulating layer 64 and the insulating layer 37 corresponds to a joint surface between the circuit chip DC2 and the memory chip DC0. Then, a conductive layer 26 in the insulating layer 37 arranged to face a conductive layer 69 in the insulating layer 64 is in contact with the conductive layer 69. That is, the joint layer B3 is in contact with the joint layer B1.

With the above configuration, the conductive layer 24a (bit line BL) in the memory region MRb is electrically connected to the N-type HV transistor, the LV transistor, and the VLV transistor provided in the sense region SRb. A conductive layer 24b in a hookup region HR is electrically connected to an HV transistor and an LV transistor provided in a transfer region XR1. A conductive layer 24c in an input/output region IOR0 is electrically connected to an LV transistor and a VLV transistor provided in an input/output region IOR2.

### 5.2 Effects According to Fifth Embodiment

According to the fifth embodiment, the first circuit provided on the substrate 60, the substrate 60, the second circuit provided on the substrate 50, and the substrate 50 are arranged in this order in the Z1 direction. As described above, even in the face-to-face structure in which the circuit chips DC1 and DC2 face each other, it is possible to achieve the comparable effect with that of the face-to-back structure in which the circuit chips DC1 and DC2 face the same direction as in the fourth embodiment.

While certain embodiments have been described, these embodiments have been presented by way of example only, and are not intended to limit the scope of the invention. Indeed, the embodiments described herein may be embodied in a variety of other forms; furthermore, various omissions, substitutions and changes in the form of the embodiments described herein may be made without departing from the spirit of the inventions. The embodiments and modifications are included in the scope and spirit of the invention and are included in the scope of the claimed inventions and their equivalents.

What is claimed is:

1. A memory device comprising:
a first chip including a memory cell array having a word line and a bit line;
a second chip including a first substrate and a first circuit provided on the first substrate, the second chip being in contact with the first chip;
a third chip including a second substrate and a second circuit provided on the second substrate, the third chip being in contact with the first chip or the second chip; and
an input/output pad,
wherein
the first chip and the second chip are arranged in this order in a first direction from the word line to the bit line,
the first circuit includes a first transistor connected to the bit line and a second transistor connected to the word line, and
the second circuit includes a third transistor connected to the input/output pad.

2. The memory device according to claim 1,
wherein
each of the first transistor and the second transistor includes a gate oxide film having a film thickness of 10 nm or more, and
the third transistor includes a gate oxide film having a film thickness of 2.5 nm or more and 3.5 nm or less.

3. The memory device according to claim 1,
wherein
the third chip is in contact with the second chip, and
the first chip, the second chip, and the third chip are arranged in this order in the first direction.

4. The memory device according to claim 3,
wherein
the input/output pad is provided at a position overlapping the memory cell array as viewed in the first direction on a surface of the third chip opposite to a joint surface with the second chip.

5. The memory device according to claim 3,
wherein
the first circuit, the first substrate, the second circuit, and the second substrate are arranged in this order in the first direction.

6. The memory device according to claim 3,
wherein
the first substrate, the first circuit, the second circuit, and the second substrate are arranged in this order in the first direction.

7. The memory device according to claim 1,
wherein
the third chip is in contact with the first chip, and
the third chip, the first chip, and the second chip are arranged in this order in the first direction.

8. The memory device according to claim 7,
wherein
the input/output pad is provided at a position overlapping the memory cell array as viewed in the first direction on a surface of the third chip opposite to a joint surface with the first chip.

9. A memory device comprising:
a first chip including a memory cell array having a plurality of word lines and a plurality of bit lines;
a second chip including a first substrate and a first circuit provided on the first substrate, the second chip being in contact with the first chip; and
a third chip including a second substrate and a second circuit provided on the second substrate, the third chip being in contact with the second chip,
wherein
the first chip, the second chip, and the third chip are arranged in this order in a first direction from the plurality of word lines to the plurality of bit lines,
the first circuit includes a sense amplifier module connected to the plurality of bit lines,
the second circuit includes a row decoder module connected to the plurality of word lines, and
the row decoder module has a first portion overlapping the sense amplifier module as viewed in the first direction.

10. The memory device according to claim 9,
wherein
the memory cell array has a first region in which each of the plurality of word lines faces the second chip without interfering with other word lines, and
the row decoder module further has a second portion that overlaps the first region as viewed in the first direction and does not overlap the sense amplifier module.

11. The memory device according to claim 10,
wherein
the memory cell array further has a second region different from the first region, and
the first portion overlaps the second region as viewed in the first direction.

12. The memory device according to claim 9,
wherein
the plurality of bit lines is arranged in a second direction intersecting the first direction,
the plurality of word lines is arranged in a third direction intersecting the first direction and the second direction,
the first circuit includes a plurality of first conductive layers arranged in the second direction at the same position in the first direction and each extending in the third direction, and
the second circuit includes a plurality of second conductive layers arranged in the third direction at the same position in the first direction and each extending in the second direction, and
a first pitch of the plurality of first conductive layers is minimum in the second chip, and
a second pitch of the plurality of second conductive layers is minimum in the third chip and is independent of the first pitch.

13. The memory device according to claim 12,
wherein
the sense amplifier module further includes a first contact connecting the first substrate and each of the plurality of first conductive layers,
the row decoder module further includes a second contact connecting the second substrate and each of the plurality of second conductive layers, and
a length of the first contact in the first direction is shorter than a length of the second contact in the first direction.

14. The memory device according to claim 9,
wherein
the plurality of bit lines is arranged in a second direction intersecting the first direction,
the plurality of word lines is arranged in a third direction intersecting the first direction and the second direction,
the second chip includes a third conductive layer containing copper and extending in the third direction in a region overlapping the row decoder module as viewed in the first direction, and
the third chip includes a fourth conductive layer containing copper and extending in the second direction in a region overlapping the sense amplifier module as viewed in the first direction.

15. The memory device according to claim 9,
wherein
a length of a power supply wiring provided in the third chip is longer than a length of a power supply wiring provided in the second chip.

16. The memory device according to claim 9,
wherein
the first circuit includes:
a fourth transistor having a gate oxide film having a film thickness of 10 nm or more;
a fifth transistor having a gate oxide film having a film thickness of 5 nm or more and 7 nm or less; and
a sixth transistor having a gate oxide film having a film thickness of 2.5 nm or more and 3.5 nm or less,
and
the second circuit includes a seventh transistor having a gate oxide film having a film thickness of 10 nm or more.

17. The memory device according to claim 16,
wherein
the seventh transistor has a triple well structure.

18. The memory device according to claim 9,
wherein
the first chip further includes a plurality of joint pads connecting each of the plurality of bit lines and the second chip, and
each of the plurality of joint pads is disposed at a position overlapping a corresponding bit line as viewed in the first direction.

19. The memory device according to claim 9,
wherein
the first circuit, the first substrate, the second circuit, and the second substrate are arranged in this order in the first direction.

20. The memory device according to claim 9,
wherein
the first substrate, the first circuit, the second circuit, and the second substrate are arranged in this order in the first direction.
